(19) United States
(12) Patent Application Publication
(10) Pub. No.: US 2020/0140975 A1
(43) Pub. Date: May 7, 2020

(54) Soldered Joint

(71) Applicant: Nihon Superior Co., Ltd., Suita-shi, Osaka (JP)

(72) Inventors: Tetsuro Nishimura, Suita-shi, Osaka (JP); Takatoshi Nishimura, Tokyo (JP); Tetsuya Akaiwa, Toyonaka-shi, Osaka (JP); Shoichi Suenaga, Toyonaka-shi, Osaka (JP)

(21) Appl. No.: 16/494,402

(22) PCT Filed: Mar. 22, 2018
(86) PCT No.: PCT/JP2018/011414

§ 371 Date: Sep. 16, 2019

(30) Foreign Application Priority Data
Mar. 23, 2017 (JP) 2017-058080

(51) Int. Cl. C22C 13/02; H05K 3/34; B23K 35/26

(52) U.S. Cl. CPC C22C 13/02; B23K 35/262; H05K 3/3463

(57) ABSTRACT

A soldered joint of the present invention is a soldered joint using a lead-free solder alloy of Sn—Cu—Ni—Bi—Ge system, and the lead-free solder alloy is an alloy in which an addition amount of Cu is 0.1 weight % to 2.0 weight %, an addition amount of Ni is 0.05 weight % to 0.5 weight %, an addition amount of Bi is 0.1 weight % to less than 8 weight %, an addition amount of Ge is 0.006 weight % to 0.1 weight %, and a balance is Sn and inevitable impurities. The soldered joint of the present invention includes a bonding portion with an object to be soldered in which Cu₃Sn is prevented from being generated.

### CROSS-REFERENCE TO RELATED APPLICATIONS

This application is the national phase under 35 U.S.C. § 371 of PCT International Application No. PCT/JP2018/011414 which has an International filing date of Mar. 22, 2018 and designated the United States of America.

### BACKGROUND

### Technical Field

The present invention relates to a soldered joint using a lead-free solder alloy.

### Description of Related Art

Recently, environmental awareness has increased, and a so-called “lead-free solder alloy” not containing lead has been used. Such a lead-free solder alloy is a solder alloy containing Sn as a main component. A representative example of a generally used lead-free solder alloy includes an Sn—Cu—based lead-free solder alloy such as Sn-3Ag-0.5Cu.

Further, in International Publication No. 2009/131114, it is disclosed that a combination of a small amount of Bi and a small amount of Ni is added to an Sn—Cu-based lead-free solder alloy so as to obtain an effect of preventing a tin pest phenomenon and of improving impact resistance.

In addition, in Japanese Patent No. 5872114, a lead-free solder alloy that contains Sn, Cu, Ni, Bi, and Ge, and is capable of retaining a bonding strength even after being subjected to a high temperature aging treatment is disclosed.

### SUMMARY

On the other hand, as described above, in a case where a copper substrate is subjected to soldering by using the lead-free solder alloy containing Sn and Cu, an intermetallic compound layer of Cu₃Sn is generated in a bonding portion. Such a Cu₃Sn layer is generated by diffusing Cu at a high temperature.

However, the Cu₃Sn layer is brittle and decreases a bonding strength of the bonding portion, and thus, the generation of the Cu₃Sn layer is not desirable.

In other words, in the case of using the lead-free solder alloy containing Sn and Cu, a device for preventing the Cu₃Sn layer from being generated is necessary in preparation for the generation of the Cu₃Sn layer and a decrease in the bonding strength due to the Cu₃Sn layer in a case where the such a bonding portion is left in a high temperature environment.

In International Publication No. 2009/131114, a small amount of Bi and Ni is added to the lead-free solder alloy containing Sn and Cu, and thus, the tin pest phenomenon is prevented, and the impact resistance is improved, but it is not possible to solve the generation of the Cu₃Sn layer in a high temperature environment and the decrease in the bonding strength due to the Cu₃Sn layer.

In addition, in Japanese Patent No. 5872114, the bonding strength can be maintained after a high temperature aging treatment, but the generation of the Cu₃Sn layer at the time of performing high temperature aging and the decrease in the bonding strength due to the Cu₃Sn layer are not devised.

The present invention has been made in consideration of such circumstances, and an object thereof is to provide a soldered joint that is capable of preventing a decrease in a bonding strength even in a high temperature environment, by preventing Cu₃Sn from being generated in a bonding portion with an object to be soldered in the case of performing soldering by using a lead-free solder alloy of Sn—Cu—Ni—Bi—Ge system.

A soldered joint according to the present invention is a soldered joint using a lead-free solder alloy, the lead-free solder alloy contains Sn, Cu, Ni, Bi and Ge, and the soldered joint includes a bonding portion with an object to be soldered in which Cu₃Sn is prevented from being generated.

In the soldered joint according to the present invention, in the lead-free solder alloy, an addition amount of Cu is 0.7 weight %, an addition amount of Ni is 0.05 weight %, an addition amount of Bi is 0.1 weight % to less than 8 weight %, an addition amount of Ge is 0.006 weight %, and a balance is Sn.

In the soldered joint according to the present invention, in the lead-free solder alloy, the addition amount of Cu is 0.1 weight % to 2.0 weight %, the addition amount of Ni is 0.05 weight %, the addition amount of Bi is 1.5 weight %, the addition amount of Ge is 0.006 weight %, and the balance is Sn.

In the soldered joint according to the present invention, in the lead-free solder alloy, the addition amount of Cu is 0.7 weight %, the addition amount of Ni is 0.05 weight % to 0.5 weight %, the addition amount of Bi is 1.5 weight %, the addition amount of Ge is 0.006 weight %, and the balance is Sn.

In the soldered joint according to the present invention, in the lead-free solder alloy, the addition amount of Cu is 0.7 weight %, the addition amount of Ni is 0.05 weight %, the addition amount of Bi is 1.5 weight %, the addition amount of Ge is 0.006 weight % to 0.1 weight %, and the balance is Sn.

In the soldered joint according to the present invention, in the lead-free solder alloy, the addition amount of Cu is 0.7 weight %, the addition amount of Ni is 0.05 weight %, the addition amount of Bi is 1.5 weight %, the addition amount of Ge is 0.006 weight %, and the balance is Sn, and any one of Ag, In, Sb, P, Mn, Au, Zn, Si, Co, Al, and Ti.

In the soldered joint according to the present invention, an addition amount of Ag is more than 0 weight % to 4.0 weight %.

In the soldered joint according to the present invention, an addition amount of In is more than 0 weight % to 51.0 weight %.

In the soldered joint according to the present invention, an addition amount of Sb is more than 0 weight % and less than 10.0 weight %.

In the soldered joint according to the present invention, an addition amount of Zn is more than 0 weight % to 0.4 weight %.

In the soldered joint according to the present invention, an addition amount of P, Mn, Au, Si, Co, Al, and Ti is more than 0 weight % to 0.1 weight %.

In the soldered joint according to the present invention, in a case where an aging treatment is performed at 150° C. for 120 hours, a change between a shear load stress before the aging treatment and a shear load stress after the aging treatment is more than or equal to 90%.

In the soldered joint according to the present invention, in a case where the aging treatment is performed at 150° C. for 120 hours, a thickness of Cu₃Sn that is formed in the bonding portion is less than or equal to 0.50 μm.

According to the present invention, in a case where a soldered joint is formed by performing soldering using a lead-free solder alloy of Sn—Cu—Ni—Bi—Ge system, it is possible to prevent Cu₃Sn from being generated in a bonding portion with an object to be soldered, and to prevent a decrease in a bonding strength due to the generation of Cu₃Sn even in a case where the soldered joint is left in a high temperature environment.

The above and further objects and features will move fully be apparent from the following detailed description with accompanying drawings.

### BRIEF DESCRIPTION OF THE SEVERAL VIEWS OF THE DRAWINGS

FIG. 1 is a schematic view schematically illustrating a shear test.

FIG. 2 is a bar graph illustrating a result of a shear test shown in Table 2.

FIG. 3 is a picture illustrating a microstructure of a bonding portion in samples according to Comparative Examples i and ii and Examples 1 to 14.

FIG. 4 is a picture illustrating the microstructure of the bonding portion in the samples according to Comparative Examples i and ii and Examples 1 to 14.

FIG. 5 is a picture illustrating the microstructure of the bonding portion in the samples according to Comparative Examples i and ii and Examples 1 to 14.

FIG. 6 is a picture illustrating the microstructure of the bonding portion in the samples according to Comparative Examples i and ii and Examples 1 to 14.

FIG. 7 is a picture illustrating the microstructure of the bonding portion in the samples according to Comparative Examples i and ii and Examples 1 to 14.

FIG. 8 is a bar graph illustrating a calculation result of a thickness of a Cu₃Sn layer shown in Table 3.

FIG. 9 is a bar graph illustrating a result of a shear test shown in Table 5.

FIG. 10 is a picture illustrating a microstructure of a bonding portion in samples according to Examples 21 to 36.

FIG. 11 is a picture illustrating the microstructure of the bonding portion in the samples according to Examples 21 to 36.

FIG. 12 is a picture illustrating the microstructure of the bonding portion in the samples according to Examples 21 to 36.

FIG. 13 is a picture illustrating the microstructure of the bonding portion in the samples according to Examples 21 to 36.

FIG. 14 is a picture illustrating the microstructure of the bonding portion in the samples according to Examples 21 to 36.

FIG. 15 is a picture illustrating the microstructure of the bonding portion in the samples according to Examples 21 to 36.

FIG. 16 is a picture illustrating the microstructure of the bonding portion in the samples according to Examples 21 to 36.

FIG. 17 is a picture illustrating the microstructure of the bonding portion in the samples according to Examples 21 to 36.

FIG. 18 is a picture illustrating the microstructure of the bonding portion in the samples according to Examples 21 to 36.

FIG. 19 is a picture illustrating the microstructure of the bonding portion in the samples according to Examples 21 to 36.

FIG. 20 is a picture illustrating the microstructure of the bonding portion in the samples according to Examples 21 to 36.

FIG. 21 is a bar graph illustrating a calculation result of a thickness of a Cu₃Sn layer shown in Table 6.

FIG. 22 is an exemplary diagram illustrating an example of a test piece that is used in evaluation of creep properties.

FIG. 23 is a graph illustrating an evaluation result of creep properties shown in Table 7.

FIG. 24 is a graph illustrating the evaluation result of the creep properties shown in Table 7.

### DETAILED DESCRIPTION

Hereinafter, an embodiment of the present invention will be described on the basis of the drawings.

The preparation of a soldered joint according to the embodiment of the present invention (hereinafter, referred to as this embodiment), and a bonding strength of a bonding portion of a soldered joint will be described. First, a substrate (an object to be soldered) subjected to a copper plating treatment is soldered with a lead-free solder alloy of Sn—Cu—Ni—Bi—Ge system. That is, a spherical solder ball formed of the lead-free solder alloy is joined to the substrate, and the bonding strength in the bonding portion between the solder ball and the substrate is measured.

TABLE 1

| | | | | | | | | DSC Measuring | | |
|---|---|---|---|---|---|---|---|---|---|---|
| | | | | | | | | Results | | |
| | | Component Composition | | | | | | Solid | Liquid | Aging |
| Item | | (unit: wt %) | | | | | | Phase | Phase | Temperature |
| | Title | Sn | Bi | Cu | Ni | Ge | Ag | Point | Point | (° C.) |
| Comparative | | R | 0.0 | 0.5 | 0.0 | 0.0 | 3.0 | 217 | 220 | 150 |
| Example i | | | | | | | | | | |
| Comparative | | R | 0.0 | 0.7 | 0.05 | 0.006 | 0.0 | 227 | 227 | 150 |
| Example ii | | | | | | | | | | |
| Example 1 | +0.1 Bi | R | 0.1 | 0.7 | 0.05 | 0.006 | 0.0 | 228 | 231 | 150 |
| Example 2 | +1 Bi | R | 1.0 | 0.7 | 0.05 | 0.006 | 0.0 | 225 | 229 | 150 |
| Example 3 | +1.5 Bi | R | 1.5 | 0.7 | 0.05 | 0.006 | 0.0 | 221 | 225 | 150 |
| Example 4 | +2 Bi | R | 2.0 | 0.7 | 0.05 | 0.006 | 0.0 | 221 | 228 | 150 |
| Example 5 | +3 Bi | R | 3.0 | 0.7 | 0.05 | 0.006 | 0.0 | 217 | 227 | 150 |
| Example 6 | +4 Bi | R | 4.0 | 0.7 | 0.05 | 0.006 | 0.0 | 212 | 226 | 150 |
| Example 7 | +6 Bi | R | 6.0 | 0.7 | 0.05 | 0.006 | 0.0 | 203 | 223 | 150 |
| Example 8 | +8 Bi | R | 8.0 | 0.7 | 0.05 | 0.006 | 0.0 | 193 | 221 | 150 |
| Example 9 | +21 Bi | R | 21 | 0.7 | 0.05 | 0.006 | 0.0 | 139 | 204 | 150 |
| Example 10 | +58 Bi | R | 58 | 0.7 | 0.05 | 0.006 | 0.0 | 138 | 148 | 150 |
| Example 11 | +0.1 Cu | R | 1.5 | 0.1 | 0.05 | 0.006 | 0.0 | 225 | 231 | 150 |
| Example 12 | +2.0 Cu | R | 1.5 | 2.0 | 0.05 | 0.006 | 0.0 | 224 | 227 | 150 |
| Example 13 | +0.5 Ni | R | 1.5 | 0.7 | 0.5 | 0.006 | 0.0 | 224 | 230 | 150 |
| Example 14 | +0.1 Ge | R | 1.5 | 0.7 | 0.05 | 0.1 | 0.0 | 223 | 228 | 150 |

Table 1 is a table showing component compositions in the lead-free solder alloys of Sn—Cu—Ni—Bi—Ge system that are used in the soldered joints according to this embodiment. In Table 1, Examples 1 to 14 are component compositions of the lead-free solder alloy of the soldered joints according to this embodiment, and Comparative Examples i and ii are component compositions of a lead-free solder alloy according to a soldered joints of a comparison target. In addition, Table 1 shows a solid phase point and a liquid phase point obtained by differential scanning calory measurement (DSC measurement).

The lead-free solder alloy in Examples 1 to 14 contains Cu, Ni, Bi, and Ge, and a balance is Sn. In the lead-free solder alloy of Examples 1 to 10, an addition amount of Bi is 0.1 weight % to 58 weight %, an addition amount of Cu is 0.7 weight %, an addition amount of Ni is 0.05 weight %, an addition amount of Ge is 0.006 weight %, and the balance is Sn. Hereinafter, the soldered joints according to Examples 1 to 10 will be also referred to as “+0.1Bi”, “+1Bi”, “+1.5Bi”, “+2Bi”, “+3Bi”, “+4Bi”, “+6Bi”, “+8Bi”, “+21Bi”, and “+58Bi”, respectively.

In the lead-free solder alloy of Examples 11 and 12, the addition amount of Bi is 1.5 weight %, the addition amount of Cu is 0.1 weight % to 2.0 weight %, the addition amount of Ni is 0.05 weight %, the addition amount of Ge is 0.006 weight %, and the balance is Sn. Hereinafter, the soldered joints according to Examples 11 and 12 will be also referred to as “+0.1Cu” and “+2.0Cu”, respectively.

In the lead-free solder alloy of Example 13, the addition amount of Bi is 1.5 weight %, the addition amount of Cu is 0.7 weight %, the addition amount of Ni is 0.5 weight %, the addition amount of Ge is 0.006 weight %, and the balance is Sn. Hereinafter, the soldered joint according to Example 13 will be also referred to as “+0.5Ni”.

In the lead-free solder alloy of Example 14, the addition amount of Bi is 1.5 weight %, the addition amount of Cu is 0.7 weight %, the addition amount of Ni is 0.05 weight %, the addition amount of Ge is 0.1 weight %, and the balance is Sn. Hereinafter, the soldered joint according to Example 14 will be also referred to as “+0.1Ge”.

On the other hand, in the lead-free solder alloy of Comparative Example i, the addition amount of Cu is 0.5 weight %, the addition amount of Ag is 3 weight %, and the balance is Sn. In addition, in the lead-free solder alloy of Comparative Example ii, the addition amount of Cu is 0.7 weight %, the addition amount of Ni is 0.05 weight %, the addition amount of Ge is 0.006 weight %, and the balance is Sn.

The substrate subjected to the copper plating treatment is soldered with the lead-free solder alloys according to Examples 1 to 14 of Table 1, and thus, the soldered joints according to this embodiment are prepared. Specifically, the preparation is performed in the following procedure.

i. In the copper plated substrate, a portion to be soldered is coated with flux of approximately 0.01 g. The dimension of the copper plating substrate is 10 mm×10 mm, and the flux is RM-5 manufactured by NIHON SUPERIOR CO., LTD.

ii. The substrate is soldered with the lead-free solder alloy according to each of Examples 1 to 14 of Table 1 (hereinafter, simply, will be referred to as the lead-free solder alloy of this embodiment) at approximately 250° C. by using a reflow method. At this time, a temperature rising rate is 1.5° C./second, and the substrate was maintained at a temperature of higher than or equal to a melting point for 50 seconds.

Accordingly, the solder ball of the lead-free solder alloy of this embodiment is formed on the substrate. Such a solder ball has a diameter of 500 μm. Hereinafter, such a solder ball was cooled at a room temperature, and then, a flux balance was washed. A shear test is performed with respect to a sample of the soldered joint obtained as described above.

Furthermore, solder balls of the lead-free solder alloys according to Comparative Examples i and ii (hereinafter, simply, will be also referred to as a lead-free solder alloy) are obtained by the same method.

An aging treatment was performed with respect to the soldered joint in which each of the solder ball of the lead-free solder alloy of this embodiment and each of the solder ball of the lead-free solder alloy of the comparative examples was joined to the substrate as described above. After that, the shear test was performed with respect to the soldered joint subjected to the aging treatment, and a bonding strength of the soldered joint of this embodiment and the soldered joint of the comparative example was measured.

In the aging treatment, the samples of the soldered joints according to Examples 1 to 14 and Comparative Examples i and ii were left to stand at 150° C. for 120 hours, and after that, were cooled at a room temperature.

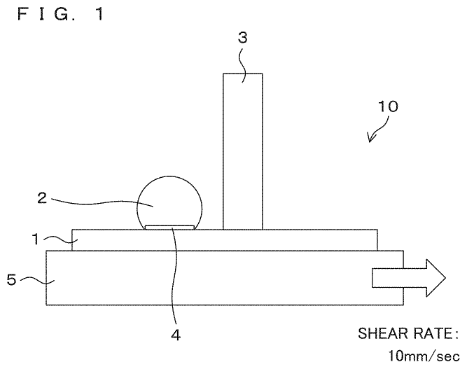

The shear test was performed with respect to the samples subjected to such an aging treatment. The shear test was performed by using a high speed shear tester 4000HS manufactured by Nordson DAGE, and a shear rate was 10 mm/sec. FIG. 1 is a schematic view schematically illustrating the shear test.

A soldered joint 10 in which a solder ball 2 is joined with a substrate 1 through a bonding portion 4 is fixed to a substrate retaining base 5. Then, a shear tool 3 is set on a traffic line of the substrate retaining base 5 that is linearly moved. The shear tool 3 is set such that when the substrate retaining base 5 is linearly moved, a lower end portion of the shear tool 3 hits only the solder ball 2 but not the substrate 1. Next, in a case where the substrate retaining base 5 is linearly moved at a rate of 10 mm/sec, the shear tool 3 and the solder ball 2 of such a sample impact with each other, and finally, the solder ball 2 is peeled off from the substrate 1. At this time, a stress sensor that is mounted on the shear tool 3 senses a shear load stress that is applied to the shear tool 3 by the solder ball 2, from the impact with respect to the solder ball 2 to the peeling. In this embodiment, in such a shear load stress, a maximum value was measured as the bonding strength of such a sample.

Results of performing the shear test with respect to the samples according to this embodiment and the comparative examples are shown in Table 2.

Specifically, 15 samples for a shear test were prepared with respect to each of Comparative Examples i and ii, and “+0.1Bi”, “+1Bi”, “+1.5Bi”, “+2Bi”, “+3Bi”, “+4Bi”, “+6Bi”, “+8Bi”, “+21Bi”, “+58Bi”, “+0.1Cu”, “+2.0Cu”, “+0.5Ni”, and “+0.1”, and the shear test was performed. Results thereof are shown in Tables 2-1, 2-2, and 2-3. Hereinafter, Tables 2-1, 2-2, and 2-3 will be simply referred to as Table 2.

TABLE 2-1

| | Comparative | | Comparative | | Example 1 | | Example 2 | | Example 3 | |
|---|---|---|---|---|---|---|---|---|---|---|
| | Example i | | Example ii | | +0.1Bi | | +1Bi | | +1.5Bi | |
| | Aging | | | | | | | | | |
| Specimen | before | after | before | after | before | after | before | after | before | after |
| 1 time | 9.9 | 8.1 | 7.8 | 7.0 | 7.8 | 7.1 | 9.2 | 8.5 | 9.6 | 9.2 |
| 2 times | 10.8 | 8.9 | 8.4 | 7.6 | 8.4 | 7.8 | 9.6 | 9.2 | 10.1 | 10.0 |
| 3 times | 9.9 | 8.2 | 7.9 | 7.0 | 7.9 | 7.2 | 9.3 | 8.6 | 9.6 | 9.3 |
| 4 times | 10.2 | 8.8 | 8.3 | 7.5 | 8.2 | 7.4 | 9.5 | 8.9 | 9.9 | 9.4 |
| 5 times | 10.4 | 8.8 | 8.3 | 7.6 | 8.3 | 7.6 | 9.5 | 8.9 | 10.0 | 9.8 |
| 6 times | 10.9 | 9.1 | 8.5 | 7.7 | 8.4 | 7.8 | 9.7 | 9.4 | 10.1 | 10.1 |
| 7 times | 9.9 | 8.2 | 8.1 | 7.2 | 7.9 | 7.2 | 9.4 | 8.7 | 9.7 | 9.3 |
| 8 times | 9.9 | 8.3 | 8.1 | 7.2 | 7.9 | 7.2 | 9.4 | 8.7 | 9.9 | 9.3 |
| 9 times | 9.7 | 7.5 | 7.8 | 7.0 | 7.8 | 7.1 | 9.1 | 8.7 | 9.7 | 10.3 |
| 10 times | 9.9 | 8.4 | 8.2 | 7.3 | 8.0 | 7.2 | 9.5 | 8.7 | 9.9 | 9.3 |
| 11 times | 11.1 | 9.3 | 8.9 | 7.8 | 8.5 | 8.0 | 9.8 | 9.6 | 10.5 | 10.4 |
| 12 times | 10.1 | 8.5 | 8.2 | 7.3 | 8.0 | 7.3 | 9.5 | 8.8 | 9.9 | 9.3 |
| 13 times | 10.2 | 8.7 | 8.2 | 7.5 | 8.1 | 7.3 | 9.5 | 8.8 | 9.9 | 9.4 |
| 14 times | 10.7 | 8.8 | 8.3 | 7.6 | 8.4 | 7.6 | 9.6 | 9.0 | 10.1 | 9.8 |
| 15 times | 11.1 | 9.2 | 8.8 | 7.7 | 8.4 | 7.9 | 9.8 | 9.6 | 10.3 | 10.3 |
| Average | 10.3 | 8.6 | 8.3 | 7.4 | 8.1 | 7.4 | 9.5 | 8.9 | 10.0 | 9.7 |
| Standard | 0.5 | 0.5 | 0.3 | 0.3 | 0.2 | 0.3 | 0.2 | 0.3 | 0.2 | 0.4 |
| Deviation | | | | | | | | | | |

| | | | | | |
|---|---|---|---|---|---|
| Strength | 83 | 89 | 92 | 94 | 97 |
| Change | | | | | |
| Rate (%) | | | | | |

TABLE 2-2

| | Example 4 | | Example 5 | | Example 6 | | Example 7 | | Example 8 | |
|---|---|---|---|---|---|---|---|---|---|---|
| | +2Bi | | +3Bi | | +4Bi | | +6Bi | | +8Bi | |
| | Aging | | | | | | | | | |
| Specimen | before | after | before | after | before | after | before | after | before | after |
| 1 time | 10.2 | 10.2 | 11.3 | 11.0 | 12.1 | 11.8 | 13.2 | 11.4 | 14.1 | 11.0 |
| 2 times | 11.0 | 10.7 | 11.8 | 11.9 | 12.6 | 12.8 | 14.2 | 14.2 | 15.2 | 13.4 |
| 3 times | 10.6 | 10.2 | 11.4 | 11.2 | 12.1 | 11.9 | 13.2 | 12.0 | 14.2 | 11.4 |
| 4 times | 10.8 | 10.6 | 11.6 | 11.7 | 12.3 | 12.4 | 13.8 | 13.7 | 14.6 | 13.0 |
| 5 times | 10.9 | 10.6 | 11.7 | 11.7 | 12.3 | 12.5 | 13.9 | 13.8 | 14.7 | 13.1 |
| 6 times | 11.1 | 10.7 | 11.9 | 11.9 | 13.0 | 12.9 | 14.3 | 14.2 | 15.3 | 13.6 |
| 7 times | 10.6 | 10.3 | 11.5 | 11.3 | 12.1 | 11.9 | 13.2 | 12.8 | 14.2 | 11.9 |
| 8 times | 10.8 | 10.3 | 11.5 | 11.6 | 12.1 | 12.0 | 13.3 | 12.8 | 14.3 | 11.9 |
| 9 times | 10.2 | 10.2 | 11.2 | 10.8 | 12.0 | 11.8 | 12.9 | 11.4 | 14.0 | 11.0 |
| 10 times | 10.8 | 10.4 | 11.5 | 11.7 | 12.1 | 12.0 | 13.4 | 13.4 | 14.3 | 12.1 |
| 11 times | 11.2 | 11.0 | 12.2 | 12.4 | 13.2 | 13.0 | 15.2 | 14.9 | 15.5 | 14.3 |
| 12 times | 10.8 | 10.4 | 11.5 | 11.7 | 12.2 | 12.2 | 13.4 | 13.5 | 14.4 | 12.1 |
| 13 times | 10.8 | 10.6 | 11.6 | 11.7 | 12.3 | 12.4 | 13.8 | 13.6 | 14.5 | 12.6 |
| 14 times | 11.0 | 10.7 | 11.7 | 11.7 | 12.6 | 12.7 | 14.2 | 14.0 | 14.8 | 13.3 |
| 15 times | 11.1 | 10.7 | 12.1 | 12.0 | 13.0 | 13.0 | 14.6 | 14.3 | 15.4 | 14.0 |
| Average | 10.8 | 10.5 | 11.6 | 11.6 | 12.4 | 12.4 | 13.8 | 13.3 | 14.6 | 12.6 |
| Standard | 0.3 | 0.2 | 0.3 | 0.4 | 0.4 | 0.4 | 0.6 | 1.0 | 0.5 | 1.0 |
| Deviation | | | | | | | | | | |

| | | | | | |
|---|---|---|---|---|---|
| Strength | 97 | 100 | 100 | 97 | 86 |
| Change | | | | | |
| Rate (%) | | | | | |

TABLE 2-3

| | Example 9 | | Example 10 | | Example 11 | | Example 12 | | Example 13 | | Example 14 | |
|---|---|---|---|---|---|---|---|---|---|---|---|---|
| | +21Bi | | +58Bi | | +0.1Cu | | +2.0Cu | | +0.5Ni | | +0.1Ge | |
| | Aging | | | | | | | | | | | |
| Specimen | before | after | before | after | before | after | before | after | before | after | before | after |
| 1 time | 13.2 | 9.3 | 10.0 | 9.5 | 9.6 | 9.4 | 10.1 | 9.5 | 10.0 | 9.4 | 10.9 | 10.0 |
| 2 times | 14.1 | 10.6 | 10.6 | 10.7 | 9.8 | 9.4 | 10.2 | 9.7 | 10.1 | 9.5 | 10.7 | 9.7 |
| 3 times | 13.2 | 9.3 | 10.0 | 9.5 | 9.3 | 9.4 | 9.9 | 8.9 | 10.0 | 8.0 | 10.8 | 9.8 |
| 4 times | 13.8 | 10.3 | 10.4 | 10.4 | 10.4 | 9.5 | 10.2 | 9.8 | 10.3 | 9.6 | 10.2 | 9.4 |
| 5 times | 13.8 | 10.4 | 10.4 | 10.5 | 9.5 | 9.4 | 10.0 | 9.2 | 10.0 | 9.4 | 11.1 | 10.1 |
| 6 times | 14.1 | 10.9 | 10.7 | 10.9 | 10.5 | 9.6 | 10.4 | 9.8 | 10.6 | 9.9 | 10.5 | 9.5 |
| 7 times | 13.5 | 9.5 | 10.0 | 9.6 | 10.2 | 9.4 | 10.2 | 9.7 | 10.2 | 9.5 | 10.4 | 9.4 |
| 8 times | 13.6 | 9.7 | 10.1 | 9.8 | 10.2 | 9.5 | 10.2 | 9.7 | 10.3 | 9.6 | 10.8 | 9.8 |
| 9 times | 13.1 | 9.2 | 9.3 | 9.0 | 10.7 | 10.0 | 10.5 | 10.1 | 10.7 | 10.0 | 9.9 | 9.1 |
| 10 times | 13.6 | 9.8 | 10.1 | 9.9 | 10.4 | 9.6 | 10.2 | 9.8 | 10.4 | 9.7 | 10.4 | 9.5 |
| 11 times | 14.2 | 11.3 | 10.9 | 11.1 | 10.4 | 9.6 | 10.3 | 9.8 | 10.4 | 9.8 | 11.2 | 10.6 |
| 12 times | 13.7 | 10.3 | 10.1 | 10.2 | 9.6 | 9.4 | 10.1 | 9.5 | 10.1 | 9.4 | 10.5 | 9.5 |
| 13 times | 13.7 | 10.3 | 10.3 | 10.3 | 10.6 | 10.0 | 10.5 | 10.0 | 10.6 | 9.9 | 10.7 | 9.7 |
| 14 times | 13.8 | 10.6 | 10.4 | 10.7 | 10.5 | 9.6 | 10.3 | 9.8 | 10.4 | 9.8 | 10.8 | 9.9 |
| 15 times | 14.1 | 11.2 | 10.7 | 11.0 | 10.5 | 9.8 | 10.4 | 10.0 | 10.6 | 9.9 | 10.8 | 9.9 |
| Average | 13.7 | 10.2 | 10.3 | 10.2 | 10.1 | 9.6 | 10.2 | 9.7 | 10.3 | 9.6 | 10.7 | 9.8 |
| Standard | 0.3 | 0.7 | 0.4 | 0.6 | 0.4 | 0.2 | 0.1 | 0.3 | 0.2 | 0.5 | 0.3 | 0.4 |
| Deviation | | | | | | | | | | | | |

| | | | | | | |
|---|---|---|---|---|---|---|
| Strength | 74 | 99 | 94 | 95 | 93 | 92 |
| Change | | | | | | |
| Rate (%) | | | | | | |

In Table 2, a “strength change rate (%)” represents a ratio of a bonding strength after the aging treatment to a bonding strength before the aging treatment in percentages.

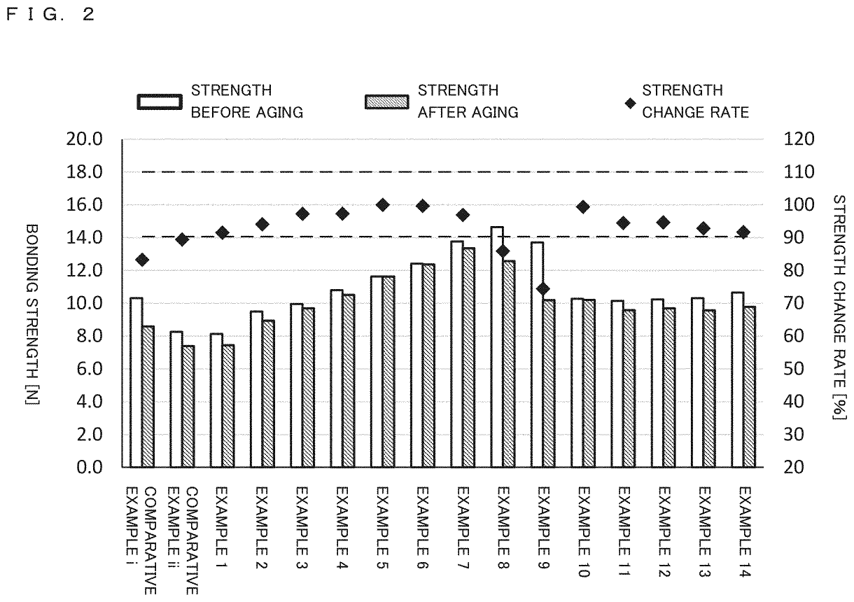

In addition, FIG. 2 is a bar graph illustrating the results of the shear test shown in Table 2. In FIG. 2, a white bar indicates an average value of the bonding strengths before the aging treatment, a black (hatching) bar indicates an average value of the bonding strengths after the aging treatment, and black lozenge indicates the strength change rate. Further, in FIG. 2, a range determined by two broken lines indicates an allowable range of the strength change rate on practical side, and is 90% to 110%.

As known from Table 2 and FIG. 2, in the samples according to Comparative Examples i and ii, it is seen that the bonding strength after the aging treatment greatly decreases compared to the bonding strength before the aging treatment. In addition, in any of Comparative Examples i and ii, the strength change rate is out of the allowable range.

In contrast, in Examples 1 to 10 in which the addition amount of Bi is changed, the strength change rate is 92% to 100%, except for the case of “+8Bi” and “+21Bi”, and is within the allowable range of the strength change rate. That is, in “+0.1Bi”, “+1Bi”, “+1.5Bi”, “+2Bi”, “+3Bi”, “+4Bi”, “+6Bi”, and “+58Bi”, the bonding strength after the aging treatment does not decrease compared to the bonding strength before the aging treatment, but is maintained.

In addition, in both of Examples 11 and 12 in which the addition amount of Cu is changed, the strength change rate is greater than or equal to 94%, and is within the allowable range of the strength change rate. That is, in “+0.1Cu” and “+2.0Cu”, the bonding strength after the aging treatment does not decrease compared to the bonding strength before the aging treatment, but is maintained.

In addition, in both of Examples 13 and 14, the strength change rate is greater than or equal to 92%, and is within the allowable range of the strength change rate. That is, in “+0.5Ni” and “+0.1Ge”, the bonding strength after the aging treatment does not decrease compared to the bonding strength before the aging treatment, but is maintained.

That is, from the results of the shear test of Example 3 and Example 13, in the lead-free solder alloy in which the addition amount of Bi is 1.5 weight %, the addition amount of Cu is 0.7 weight %, the addition amount of Ni is 0.05 to 0.5 weight %, the addition amount of Ge is 0.006 weight %, and the balance is Sn, the strength change rate is greater than or equal to 93%, and is within the allowable range of the strength change rate.

In addition, from the results of the shear test of Example 3 and Example 14, in the lead-free solder alloy in which the addition amount of Bi is 1.5 weight %, the addition amount of Cu is 0.7 weight %, the addition amount of Ni is 0.05 weight %, the addition amount of Ge is 0.006 weight % to 0.1 weight %, and the balance is Sn, the strength change rate is greater than or equal to 92%, and is within the allowable range of the strength change rate.

From the results described above, in the soldered joint 10 using the lead-free solder alloy of Sn—Cu—Ni—Bi—Ge system, in a case where the aging treatment is performed at 150° C. for 120 hours, a change between the bonding strength before the aging treatment and the bonding strength after the aging treatment (the shear load stress) is greater than or equal to 90%, and thus, it is necessary to have the compositions according to Examples 1 to 7, and 10 to 14. However, in Example 10, the strength change rate is 99%, but the addition amount of Bi is 58 weight %, which is not easy for practical use. Accordingly, the compositions corresponding to Examples 1 to 7, and 11 to 14 is preferable.

That is, it is preferable that the addition amount of Cu is 0.7 weight %, the addition amount of Ni is 0.05 weight %, the addition amount of Bi is more than or equal to 0.1 weight % and less than 8 weight %, the addition amount of Ge is 0.006 weight %, and the balance is Sn. Alternatively, it is preferable that the addition amount of Cu is 0.1 weight % to 2.0 weight %, the addition amount of Ni is 0.05 weight %, the addition amount of Bi is 1.5 weight %, the addition amount of Ge is 0.006 weight %, and the balance is Sn. Alternatively, it is preferable that the addition amount of Cu is 0.7 weight %, the addition amount of Ni is 0.5 weight %, the addition amount of Bi is 1.5 weight %, the addition amount of Ge is 0.006 weight %, and the balance is Sn. Alternatively, it is preferable that the addition amount of Cu is 0.7 weight %, the addition amount of Ni is 0.05 weight %, the addition amount of Bi is 1.5 weight %, the addition amount of Ge is 0.1 weight %, and the balance is Sn.

As described above, in the samples of Examples 1 to 7 and 10 to 14 according to this embodiment to which Bi is added, the bonding strength is maintained before and after the aging treatment, and the bonding strength does not decrease, compared to Comparative Examples i and ii to which Bi is not added. From such results, it was predicted that the addition of Bi affected the maintenance of the bonding strength in some way.

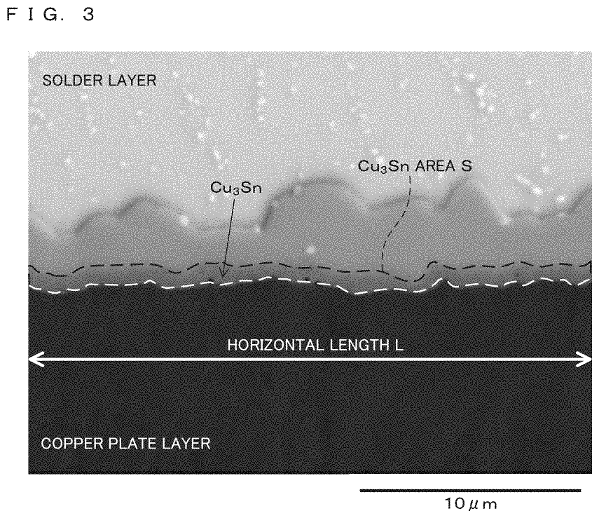

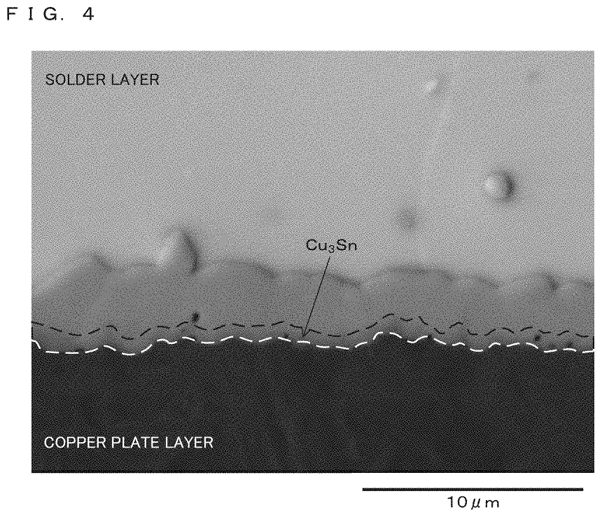

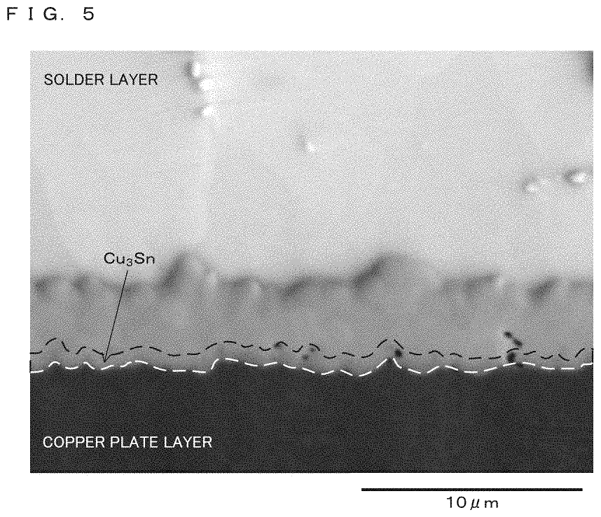

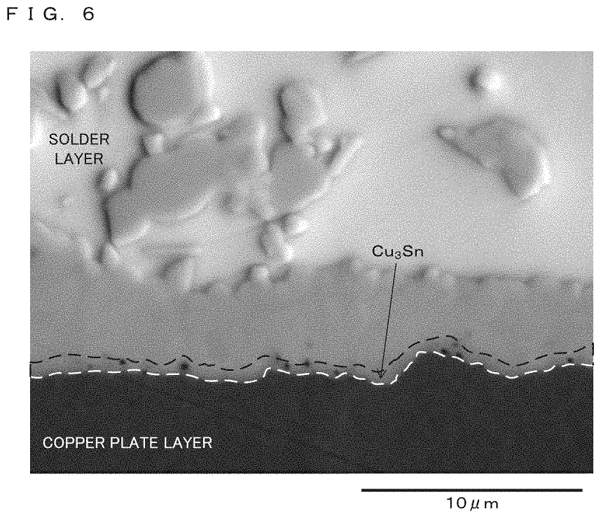

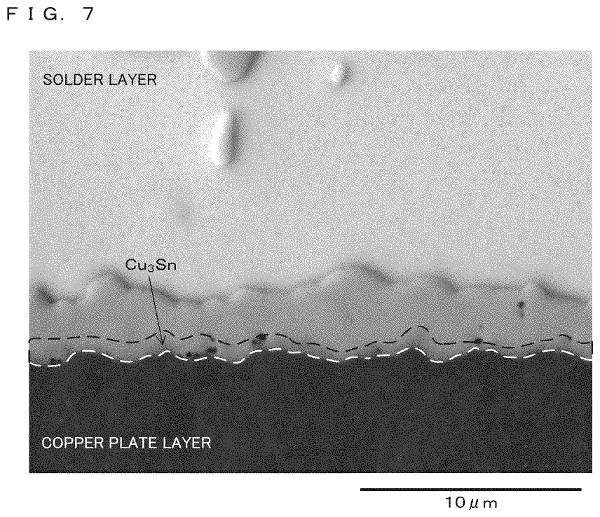

In order to confirm this, the microstructure of the bonding portion 4 in the samples according to this embodiment and the comparative examples was observed. FIG. 3 to FIG. 7 are pictures illustrating the microstructure of the bonding portion 4 in the samples according to Comparative Examples i and ii and Examples 1 to 14. FIG. 3 is a picture illustrating the microstructure of the bonding portion of the soldered joint of Comparative Example i, FIG. 4 is a picture illustrating the microstructure of the bonding portion 4 of the soldered joint 10 of Example 6 (“+4Bi”), FIG. 5 is a picture illustrating the microstructure of the bonding portion 4 of the soldered joint 10 of Example 11 (“+0.1”). FIG. 6 is a picture illustrating the microstructure of the bonding portion 4 of the soldered joint 10 of Example 13 (“+0.5Ni”), and FIG. 7 is a picture illustrating the microstructure of the bonding portion 4 of the soldered joint 10 of Example 14 (“+0.1Ge”).

FIG. 3 to FIG. 7 are pictures obtained by capturing the microstructure of the bonding portion 4 of each of the samples by using an electron scanning microscope (SEM) after performing the aging treatment with respect to the sample of the soldered joint according to the comparative examples and the examples of this embodiment at 150° C. for 120 hours.

As known from FIG. 3 to FIG. 7, in any of the samples according to this embodiment and the comparative examples, a Cu₃Sn intermetallic compound layer exists in the bonding portion 4 between the solder ball 2 and the substrate 1. The thicknesses of the Cu₃Sn layers in the comparative examples and the examples of this embodiment were calculated by the following formula, and were compared to each other.

Cu₃Sn Area S/Horizontal Length L=Thickness of Cu₃Sn Layer (Formula)

Here, as illustrated in FIG. 3, the Cu—Sn area S is the area of the Cu—Sn layer that is visible (two-dimensionally) on each of the pictures. In addition, the horizontal length L is the length of the Cu₃Sn layer in a direction intersecting with a thickness direction of the Cu₃Sn layer, that is, a direction along the surface of the substrate 1.

The calculated thickness of the Cu3Sn layer is shown in Table 3. In Table 3, an average thickness of the Cu₃Sn layer of the soldered joints according to Examples 1 to 14 and Comparative Examples i and ii before and after the aging treatment is shown. In addition, for comparison, the strength change rate in Table 2 is also shown. As known from Table 3, in most cases, the Cu₃Sn layer does not exist before the aging treatment, but in the case of Comparative Example i and Example 9, the Cu₃Sn layer exists even before the aging treatment.

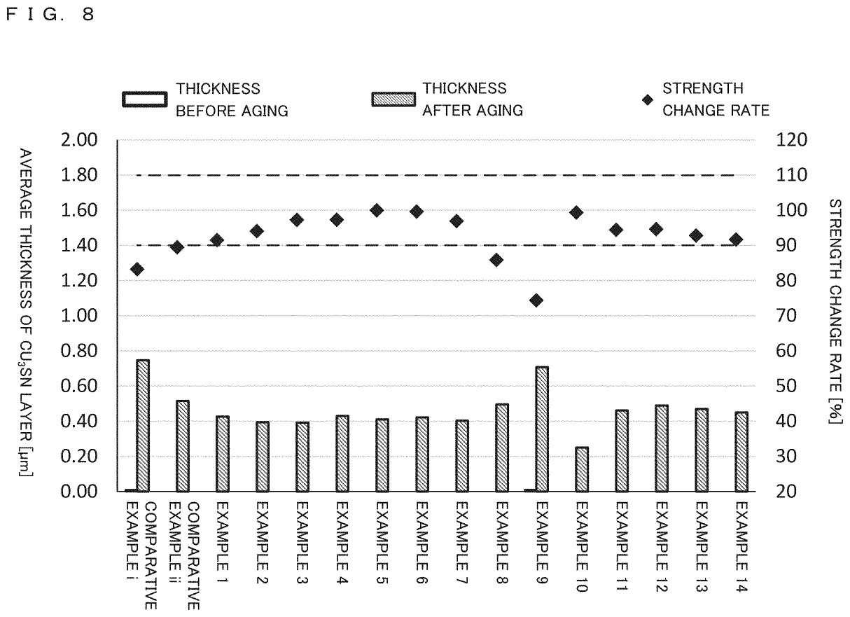

FIG. 8 is a bar graph illustrating a calculation result of the thickness of the Cu₃Sn layer shown in Table 3. In FIG. 8, a white bar (only Comparative Example i and Example 9) indicates the average thickness of the Cu₃Sn layer before the aging treatment, a black (hatching) bar indicates the average thickness of the Cu3Sn layer after the aging treatment, and a black lozenge indicates the strength change rate. Further, in FIG. 8, a range determined by two broken lines indicates the allowable range of the strength change rate as with FIG. 2.

Comparing the case of Comparative Examples i and ii and Examples 8 and 9 in which the strength change rate is out of the allowable range, to the case of Examples 1 to 7 and 10 to 14 in which the strength change rate is within the allowable range, it is seen that the thickness of the Cu₃Sn layer is divided at 0.49 μm. Specifically, in the case of Examples 1 to 7 and 10 to 14 in which in which the strength change rate is within the allowable range, the thickness of the Cu₃Sn layer is less than or equal to 0.49 μm. On the other hand, in the case of Comparative Examples i and ii and Examples 8 and 9 in which the strength change rate is out of the allowable range, the thickness of the Cu₃Sn layer is greater than or equal to 50 μm.

Further, in the case of Examples 7 to 9, it is possible to confirm that the thickness of the Cu₃Sn layer increases in proportion as the addition amount of Bi increases to 21 weight % from 6 weight %, whereas the strength change rate decreases. That is, it is known that an increase in the thickness of the Cu₃Sn layer causes a decrease in the bonding strength after a high temperature aging treatment.

As described above, in the soldered joint 10 using the lead-free solder alloy of Sn—Cu—Ni—Bi—Ge system, in a case where the aging treatment is performed at 150° C. for 120 hours, it is necessary to suppress the thickness of Cu₃Sn that is formed in the bonding portion 4 to be less than or equal to 0.49 μm, in order to set a change between the bonding strength before the aging treatment and the bonding strength after the aging treatment to be greater than or equal to 90%.

In the above description, in the lead-free solder alloy of Sn—Cu—Ni—Bi—Ge system, a case where the addition amount of Bi, Cu, Ni, and Ge is changed has been described as an example, but the present invention is not limited thereto.

For example, one additive of Ag, In, Sb, P, Mn, Au, Zn, Ga, Si, Co, Al, and Ti may be further added to the lead-free solder alloy of Sn—Cu—Ni—Bi—Ge system according to Examples 1 to 14 described above. In a case where such an additive is added, it is needless to say that the effects described above are obtained.

Hereinafter, in a case where any additive is added to the lead-free solder alloy of Sn—Cu—Ni—Bi—Ge system according to this embodiment, the strength change rate and a change in the thickness of the Cu₃Sn layer will be described.

Table 4 shows a component composition of the additive that is added to the lead-free solder alloy of Sn—Cu—Ni—Bi—Ge system according to this embodiment. Here, in the lead-free solder alloy of Sn—Cu—Ni—Bi—Ge system according to this embodiment, the addition amount of Cu is 0.7 weight %, the addition amount of Ni is 0.05 weight %, the addition amount of Bi is 1.5 weight %, the addition amount of Ge is 0.006 weight %, and the balance is Sn.

TABLE 4

| | | | | | | | | | | | | | DSC Measuring | | |
|---|---|---|---|---|---|---|---|---|---|---|---|---|---|---|---|
| | | | | | | | | | | | | | Results | | |
| | | Component Composition | | | | | | | | | | | Solid | Liquid | Aging |
| Item | | (unit: wt %) | | | | | | | | | | | Phase | Phase | Temperature |
| | Title | Ag | In | Sb | P | Mn | Au | Zn | Si | Co | Al | Ti | Point | Point | (° C.) |
| Comparative | | 3.0 | 0.0 | 0.0 | 0.0 | 0.0 | 0.0 | 0.0 | 0.0 | 0.0 | 0.0 | 0.0 | 217 | 220 | 150 |
| Example i | | | | | | | | | | | | | | | |
| Comparative | | 0.0 | 0.0 | 0.0 | 0.0 | 0.0 | 0.0 | 0.0 | 0.0 | 0.0 | 0.0 | 0.0 | 227 | 227 | 150 |
| Example ii | | | | | | | | | | | | | | | |
| Example 21 | +1 Ag | 1.0 | 0.0 | 0.0 | 0.0 | 0.0 | 0.0 | 0.0 | 0.0 | 0.0 | 0.0 | 0.0 | 213 | 225 | 150 |
| Example 22 | +2 Ag | 2.0 | 0.0 | 0.0 | 0.0 | 0.0 | 0.0 | 0.0 | 0.0 | 0.0 | 0.0 | 0.0 | 213 | 222 | 150 |
| Example 23 | +3 Ag | 3.0 | 0.0 | 0.0 | 0.0 | 0.0 | 0.0 | 0.0 | 0.0 | 0.0 | 0.0 | 0.0 | 213 | 220 | 150 |
| Example 24 | +4 Ag | 4.0 | 0.0 | 0.0 | 0.0 | 0.0 | 0.0 | 0.0 | 0.0 | 0.0 | 0.0 | 0.0 | 213 | 219 | 150 |
| Example 25 | +6 In | 0.0 | 6.0 | 0.0 | 0.0 | 0.0 | 0.0 | 0.0 | 0.0 | 0.0 | 0.0 | 0.0 | 207 | 217 | 150 |
| Example 26 | +51 In | 0.0 | 51.0 | 0.0 | 0.0 | 0.0 | 0.0 | 0.0 | 0.0 | 0.0 | 0.0 | 0.0 | 112 | 119 | 120 |
| Example 27 | +5 Sb | 0.0 | 0.0 | 5.0 | 0.0 | 0.0 | 0.0 | 0.0 | 0.0 | 0.0 | 0.0 | 0.0 | 230 | 237 | 150 |
| Example 28 | +10 Sb | 0.0 | 0.0 | 10.0 | 0.0 | 0.0 | 0.0 | 0.0 | 0.0 | 0.0 | 0.0 | 0.0 | 232 | 267 | 150 |
| Example 29 | +0.1 P | 0.0 | 0.0 | 0.0 | 0.1 | 0.0 | 0.0 | 0.0 | 0.0 | 0.0 | 0.0 | 0.0 | 223 | 228 | 150 |
| Example 30 | +0.1 Mn | 0.0 | 0.0 | 0.0 | 0.0 | 0.1 | 0.0 | 0.0 | 0.0 | 0.0 | 0.0 | 0.0 | 223 | 229 | 150 |
| Example 31 | +0.1 Au | 0.0 | 0.0 | 0.0 | 0.0 | 0.0 | 0.1 | 0.0 | 0.0 | 0.0 | 0.0 | 0.0 | 223 | 228 | 150 |
| Example 32 | +0.4 Zn | 0.0 | 0.0 | 0.0 | 0.0 | 0.0 | 0.0 | 0.4 | 0.0 | 0.0 | 0.0 | 0.0 | 221 | 227 | 150 |
| Example 33 | +0.1 Si | 0.0 | 0.0 | 0.0 | 0.0 | 0.0 | 0.0 | 0.0 | 0.1 | 0.0 | 0.0 | 0.0 | 223 | 228 | 150 |
| Example 34 | +0.1 Co | 0.0 | 0.0 | 0.0 | 0.0 | 0.0 | 0.0 | 0.0 | 0.0 | 0.1 | 0.0 | 0.0 | 224 | 229 | 150 |
| Example 35 | +0.1 Al | 0.0 | 0.0 | 0.0 | 0.0 | 0.0 | 0.0 | 0.0 | 0.0 | 0.0 | 0.1 | 0.0 | 222 | 229 | 150 |
| Example 36 | +0.1 Ti | 0.0 | 0.0 | 0.0 | 0.0 | 0.0 | 0.0 | 0.0 | 0.0 | 0.0 | 0.0 | 0.1 | 223 | 229 | 150 |

In Table 4, Examples 21 to 36 have the component compositions of the lead-free solder alloy of the soldered joint 10 according to this embodiment, and Comparative Examples i and ii, as described above, have the component compositions of the lead-free solder alloy according to the soldered joint of the comparison target. In addition, Table 4 shows a solid phase point and a liquid phase point obtained by differential scanning calory measurement (DSC measurement), in Examples 21 to 36 and Comparative Examples i and ii.

In the lead-free solder alloys of Examples 21 to 24, 1 weight % to 4 weight % of Ag is added. Hereinafter, the soldered joints 10 according to Examples 21 to 24 will be also referred to as “+1Ag”, “+2Ag”, “+3Ag”, and “+4Ag”, respectively.

In the lead-free solder alloys of Examples 25 and 26, 6 weight % to 51 weight % of In is added. Hereinafter, the soldered joints 10 according to Examples 25 and 26 will be also referred to as “+6In” and “+51In”, respectively.

In the lead-free solder alloys of Examples 27 and 28, 5 weight % to 10 weight % of Sb is added. Hereinafter, the soldered joints 10 according to Examples 27 and 28 will be also referred to as “+5Sb” and “+10Sb”, respectively.

In the lead-free solder alloys of Examples 29 to 31 and 33 to 36, 0.1 weight % of each of P, Mn, Au, Si, Co, Al, and Ti is added. Hereinafter, the soldered joints 10 according to Examples 29 to 31 and 33 to 36 will be also referred to as “+0.1P”, “+0.1Mn”, “+0.1Au”, “+0.1Si”, “+0.1Co”, “+0.1Al”, and “+0.1Ti”, respectively.

In the lead-free solder alloy of Example 32, 0.4 weight % of Zn is added. Hereinafter, the soldered joint 10 according to Example 32 will be also referred to as “+0.4 Zn”.

On the other hand, the component compositions of the lead-free solder alloys of Comparative Examples i and ii have been already described, and thus, the detailed description will be omitted.

The soldered joints 10 according to this embodiment, as illustrated in FIG. 1, were prepared by using the lead-free solder alloys according to Examples 21 to 36 of Table 4. The detailed preparation method of the soldered joints 10 has been already described, and thus, here, the description will be omitted.

The aging treatment was performed with respect to the soldered joints 10 according to this embodiment and the soldered joints according to the comparative examples that were obtained. After that, the shear test was performed with respect to the soldered joints subjected to the aging treatment, and the bonding strength in the soldered joints 10 of this embodiment and the soldered joints of the comparative example was measured. The aging treatment and the shear test have been already described, and thus, here, the description will be omitted.

15 samples for a shear test were prepared with respect to each of “+1Ag”, “+2Ag”, “+3Ag”, “+4Ag”, “+6In”, “+5In”, “+5Sb”, “+10Sb”, “+0.1P”, “+0.1Mn”, “+0.1Au”, “+0.4Zn”, “+0.1Si”, “+0.1Co”, “+0.1Al”, and “+0.1Ti”, and the shear test was performed. Results thereof are shown in Tables 5-1, 5-2, 5-3, and 5-4. Hereinafter, Tables 5-1, 5-2, 5-3, and 5-4 will be simply referred to as Table 5.

TABLE 5-1

| | Comparative | | Comparative | | Example 21 | | Example 22 | | Example 23 | |
|---|---|---|---|---|---|---|---|---|---|---|
| | Example i | | Example ii | | +1Ag | | +2Ag | | +3Ag | |
| | Aging | | | | | | | | | |
| Specimen | before | after | before | after | before | after | before | after | before | after |
| 1 time | 9.9 | 8.1 | 7.8 | 7.0 | 10.3 | 9.8 | 10.7 | 10.3 | 11.0 | 10.6 |
| 2 times | 10.8 | 8.9 | 8.4 | 7.6 | 10.5 | 9.9 | 10.9 | 10.6 | 11.6 | 10.8 |
| 3 times | 9.9 | 8.2 | 7.9 | 7.0 | 10.1 | 9.7 | 10.6 | 9.9 | 9.6 | 10.3 |
| 4 times | 10.2 | 8.8 | 8.3 | 7.5 | 11.0 | 10.4 | 11.4 | 11.2 | 12.0 | 11.3 |
| 5 times | 10.4 | 8.8 | 8.3 | 7.6 | 10.1 | 9.7 | 10.6 | 10.2 | 10.8 | 10.4 |
| 6 times | 10.9 | 9.1 | 8.5 | 7.7 | 11.1 | 10.9 | 11.8 | 11.6 | 12.4 | 11.9 |
| 7 times | 9.9 | 8.2 | 8.1 | 7.2 | 10.6 | 10.1 | 11.0 | 11.0 | 11.7 | 10.8 |
| 8 times | 9.9 | 8.3 | 8.1 | 7.2 | 10.6 | 10.3 | 11.1 | 11.1 | 11.7 | 11.2 |
| 9 times | 9.7 | 7.5 | 7.8 | 7.0 | 12.5 | 11.2 | 13.0 | 12.3 | 13.6 | — |
| 10 times | 9.9 | 8.4 | 8.2 | 7.3 | 11.0 | 10.4 | 11.5 | 11.2 | 12.1 | 11.5 |
| 11 times | 11.1 | 9.3 | 8.9 | 7.8 | 11.0 | 10.5 | 11.5 | 11.2 | 12.2 | 11.7 |
| 12 times | 10.1 | 8.5 | 8.2 | 7.3 | 10.4 | 9.8 | 10.9 | 10.5 | 11.2 | 10.8 |
| 13 times | 10.2 | 8.7 | 8.2 | 7.5 | 11.2 | 11.0 | 12.6 | 11.9 | 13.1 | 12.6 |
| 14 times | 10.7 | 8.8 | 8.3 | 7.6 | 11.1 | 10.8 | 11.7 | 11.3 | 12.4 | 11.8 |
| 15 times | 11.1 | 9.2 | 8.8 | 7.7 | 11.1 | 11.0 | 12.0 | 11.7 | 12.8 | 12.4 |
| Average | 10.3 | 8.6 | 8.3 | 7.4 | 10.9 | 10.4 | 11.4 | 11.1 | 11.9 | 11.3 |
| Standard | 0.5 | 0.5 | 0.3 | 0.3 | 0.6 | 0.5 | 0.7 | 0.7 | 1.0 | 0.7 |
| Deviation | | | | | | | | | | |

| | | | | | |
|---|---|---|---|---|---|
| Strength | 83 | 89 | 95 | 97 | 95 |
| Change | | | | | |
| Rate (%) | | | | | |

TABLE 5-2

| | Example 24 | | Example 25 | | Example 26 | | Example 27 | | Example 28 | |
|---|---|---|---|---|---|---|---|---|---|---|
| | +4Ag | | +6In | | +51In | | +5Sb | | + 10Sb | |
| | Aging | | | | | | | | | |
| Specimen | before | after | before | after | before | after | before | after | before | after |
| 1 time | 11.9 | 11.0 | 12.0 | 11.9 | 2.7 | 2.8 | 11.9 | 11.2 | 11.0 | 9.6 |
| 2 times | 12.1 | 11.2 | 12.6 | 11.9 | 2.7 | 2.9 | 12.0 | 11.3 | 11.8 | 9.7 |
| 3 times | 11.8 | 11.0 | 12.0 | 11.6 | 2.6 | 2.8 | 11.6 | 11.2 | 9.9 | 8.9 |
| 4 times | 12.2 | 11.3 | 12.8 | 12.3 | 2.8 | 2.9 | 12.1 | 11.5 | 12.5 | 10.6 |
| 5 times | 11.8 | 11.0 | 12.0 | 11.7 | 2.6 | 2.8 | 11.6 | 11.2 | 10.4 | 9.2 |
| 6 times | 12.6 | 11.8 | 13.2 | 12.6 | 3.0 | 3.0 | 12.5 | 12.0 | 13.0 | 12.0 |
| 7 times | 12.1 | 11.2 | 12.6 | 12.0 | 2.7 | 2.9 | 12.0 | 11.5 | 11.9 | 10.1 |
| 8 times | 12.2 | 11.3 | 12.7 | 12.1 | 2.8 | 2.9 | 12.0 | 11.5 | 12.5 | 10.5 |
| 9 times | 12.9 | 12.5 | 13.3 | 13.4 | 3.1 | 3.7 | 12.9 | 12.8 | 13.1 | 13.4 |
| 10 times | 12.3 | 11.4 | 12.9 | 12.3 | 2.8 | 3.0 | 12.2 | 11.6 | 12.6 | 11.2 |
| 11 times | 12.4 | 11.5 | 13.0 | 12.3 | 2.9 | 3.0 | 12.4 | 11.8 | 12.9 | 11.2 |
| 12 times | 12.0 | 11.1 | 12.1 | 11.9 | 2.7 | 2.8 | 11.9 | 11.2 | 11.6 | 9.6 |
| 13 times | 12.9 | 12.3 | 13.2 | 13.3 | 3.0 | 3.1 | 12.8 | 12.1 | 13.1 | 12.4 |
| 14 times | 12.5 | 11.7 | 13.1 | 12.4 | 2.9 | 3.0 | 12.4 | 11.9 | 13.0 | 11.8 |
| 15 times | 12.7 | 12.0 | 13.2 | 12.9 | 3.0 | 3.0 | 12.6 | 12.1 | 13.0 | 12.4 |
| Average | 12.3 | 11.5 | 12.7 | 12.3 | 2.8 | 3.0 | 12.2 | 11.7 | 12.1 | 10.8 |
| Standard | 0.4 | 0.5 | 0.5 | 0.5 | 0.1 | 0.2 | 0.4 | 0.4 | 1.0 | 1.3 |
| Deviation | | | | | | | | | | |

| | | | | | |
|---|---|---|---|---|---|
| Strength | 93 | 97 | 105 | 96 | 89 |
| Change | | | | | |
| Rate (%) | | | | | |

TABLE 5-3

| | Example 29 | | Example 30 | | Example 31 | | Example 32 | | Example 33 | |
|---|---|---|---|---|---|---|---|---|---|---|
| | +0.1P | | +0.1Mn | | 0.1Au | | 0.4Zn | | +0.1Si | |
| | Aging | | | | | | | | | |
| Specimen | before | after | before | after | before | after | before | after | before | after |
| 1 time | 10.1 | 9.7 | 10.4 | 10.0 | 10.5 | 10.2 | 10.5 | 10.7 | 10.4 | 10.2 |
| 2 times | 9.7 | 9.2 | 10.2 | 9.8 | 10.2 | 9.7 | 10.1 | 9.5 | 10.2 | 9.9 |
| 3 times | 10.0 | 9.4 | 10.3 | 9.8 | 10.3 | 9.9 | 10.1 | 9.5 | 10.2 | 9.9 |
| 4 times | 9.3 | 8.8 | 9.8 | 9.4 | 9.8 | 9.5 | 9.6 | 8.9 | 9.8 | 9.7 |
| 5 times | 10.1 | 9.9 | 10.5 | 10.1 | 10.6 | 10.3 | 10.6 | 10.8 | 10.5 | 10.4 |
| 6 times | 9.7 | 9.1 | 10.2 | 9.5 | 10.1 | 9.6 | 10.0 | 9.2 | 10.0 | 9.8 |
| 7 times | 9.5 | 8.8 | 10.0 | 9.4 | 9.8 | 9.5 | 9.7 | 9.1 | 9.9 | 9.7 |
| 8 times | 10.0 | 9.4 | 10.3 | 9.8 | 10.3 | 10.0 | 10.1 | 10.0 | 10.3 | 10.0 |
| 9 times | 9.1 | 8.8 | 9.5 | 9.3 | 9.7 | 9.4 | 9.5 | 8.9 | 9.6 | 9.5 |
| 10 times | 9.6 | 8.9 | 10.1 | 9.5 | 10.0 | 9.6 | 9.7 | 9.2 | 9.9 | 9.8 |
| 11 times | 10.2 | 9.9 | 10.6 | 10.2 | 10.7 | 10.4 | 10.6 | 10.8 | 10.5 | 10.5 |
| 12 times | 9.6 | 8.9 | 10.1 | 9.5 | 10.1 | 9.6 | 10.0 | 9.2 | 10.0 | 9.8 |
| 13 times | 9.7 | 9.2 | 10.2 | 9.7 | 10.1 | 9.7 | 10.0 | 9.4 | 10.0 | 9.9 |
| 14 times | 10.1 | 9.5 | 10.4 | 10.0 | 10.4 | 10.1 | 10.3 | 10.3 | 10.4 | 10.2 |
| 15 times | 10.0 | 9.4 | 10.3 | 9.9 | 10.3 | 10.0 | 10.2 | 10.0 | 10.3 | 10.1 |
| Average | 9.8 | 9.3 | 10.2 | 9.7 | 10.2 | 9.8 | 10.1 | 9.7 | 10.1 | 10.0 |
| Standard | 0.3 | 0.4 | 0.3 | 0.3 | 0.3 | 0.3 | 0.3 | 0.7 | 0.3 | 0.3 |
| Deviation | | | | | | | | | | |

| | | | | | |
|---|---|---|---|---|---|
| Strength | 95 | 95 | 96 | 96 | 98 |
| Change | | | | | |
| Rate (%) | | | | | |

TABLE 5-4

| | Example 34 | | Example 35 | | Example 36 | |
|---|---|---|---|---|---|---|
| | +0.1Co | | +0.1Al | | +0.1Ti | |
| | Aging | | | | | |
| Specimen | before | after | before | after | before | after |
| 1 time | 10.4 | 10.9 | 10.9 | 11.1 | 10.4 | 10.6 |
| 2 times | 10.1 | 9.8 | 10.1 | 9.9 | 9.9 | 9.7 |
| 3 times | 10.2 | 9.9 | 10.2 | 10.0 | 9.9 | 10.1 |
| 4 times | 9.7 | 9.4 | 9.6 | 9.0 | 9.4 | 9.0 |
| 5 times | 10.5 | 11.0 | 11.1 | 11.2 | 10.4 | 10.7 |
| 6 times | 9.9 | 9.7 | 9.9 | 9.3 | 9.8 | 9.3 |
| 7 times | 9.8 | 9.4 | 9.6 | 9.1 | 9.6 | 9.1 |
| 8 times | 10.3 | 10.3 | 10.3 | 10.0 | 10.0 | 10.2 |
| 9 times | 9.7 | 9.3 | 9.3 | 9.0 | 9.3 | 9.0 |
| 10 times | 9.8 | 9.4 | 9.8 | 9.2 | 9.7 | 9.1 |
| 11 times | 10.6 | 11.2 | 11.9 | 11.6 | 10.5 | 10.9 |
| 12 times | 9.9 | 9.5 | 9.8 | 9.3 | 9.8 | 9.2 |
| 13 times | 10.1 | 9.7 | 10.0 | 9.8 | 9.9 | 9.5 |
| 14 times | 10.4 | 10.7 | 10.7 | 10.9 | 10.2 | 10.5 |
| 15 times | 10.3 | 10.4 | 10.5 | 10.2 | 10.0 | 10.3 |
| Average | 10.1 | 10.0 | 10.2 | 10.0 | 9.9 | 9.8 |
| Standard | 0.3 | 0.6 | 0.7 | 0.8 | 0.4 | 0.7 |
| Deviation | | | | | | |

| | | | |
|---|---|---|---|
| Strength | 99 | 97 | 99 |
| Change | | | |
| Rate (%) | | | |

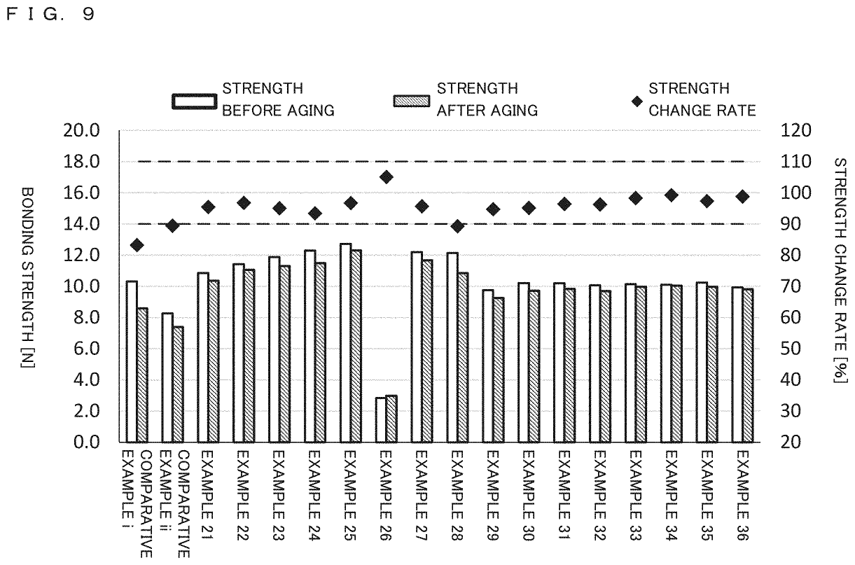

In addition, FIG. 9 is a bar graph illustrating the results of the shear test shown in Table 5. In FIG. 9, a white bar indicates the average value of the bonding strengths before the aging treatment, a black bar indicates the average value of the bonding strengths after the aging treatment, and a black lozenge indicates the strength change rate. Further, in FIG. 9, a range determined by two broken lines indicates the allowable range of the strength change rate.

As known from Table 5 and FIG. 9, in the samples according to Comparative Examples i and ii, the bonding strength after the aging treatment greatly decreases, and the strength change rate is out of the allowable range.

In contrast, in Examples 21 to 24 in which the addition amount of Ag is changed, the strength change rate is 93 to 97%, and is within the allowable range of the strength change rate. That is, in “+1Ag”, “+2Ag”, “+3Ag”, and “+4Ag”, the bonding strength after the aging treatment does not decrease compared to the bonding strength before the aging treatment, but is maintained.

In addition, in both of Examples 25 and 26 in which the addition amount of In is changed, the strength change rate is 97% to 105%, and is within the allowable range of the strength change rate. That is, in “+6In” and “+51In”, the bonding strength after the aging treatment does not decrease compared to the bonding strength before the aging treatment, but is maintained.

In addition, in Examples 27 and 28 in which the addition amount of Sb is changed, the strength change rate of Example 27 in which the addition amount of Sb is 5 weight % is 96%, and is within the allowable range of the strength change rate, but the strength change rate of Example 28 in which the addition amount of Sb is 10 weight % is 89%, and thus, is out of the allowable range of the strength change rate. That is, only in the case of “+10Sb”, the bonding strength after the aging treatment decreases compared to the bonding strength before the aging treatment.

In addition, in all of Examples 29 to 36, the strength change rate is greater than or equal to 95%, and is within the allowable range of the strength change rate. That is, in “+0.1P”, “+0.1Mn”, “+0.1Au”, “+0.4Zn”, “+0.1Si”, “+0.1Co”, “+0.1A1”, and “+0.1Ti”, the bonding strength after the aging treatment does not decrease compared to the bonding strength before the aging treatment, but is maintained.

From the results described above, in the soldered joint 10 using the lead-free solder alloy of Sn—Cu—Ni—Bi—Ge system containing the additive, in a case where the aging treatment was performed at 150° C. for 120 hours, the compositions according to Examples 21 to 27 and 29 to 36 may be used in order to set a change between the bonding strength before the aging treatment and the bonding strength after the aging treatment to be greater than or equal to 90%. However, in Example 26, the strength change rate is 105%, but the addition amount of In is 51 weight %, which is not easy for practical use.

That is, in a case where the additive is added to the lead-free solder alloy in which the addition amount of Cu is 0.7 weight %, the addition amount of Ni is 0.05 weight %, the addition amount of Bi is 1.5 weight %, the addition amount of Ge is 0.006 weight %, and the balance is Sn, the compositions corresponding to Examples 21 to 25, 27, and 29 to 36 are preferable. Specifically, it is preferable that the addition amount of Ag is more than 0 weight % and less than or equal to 4.0 weight %. It is preferable that the addition amount of In is more than 0 weight % and less than or equal to 51.0 weight %. It is preferable that the addition amount of Sb is more than 0 weight % and less than 10.0 weight %. It is preferable that the addition amount of Zn is more than 0 weight % and less than or equal to 0.4 weight %. It is preferable that the addition amount of P, Mn, Au, Si, Co, Al, and Ti is more than 0 weight % and less than or equal to 0.1 weight %.

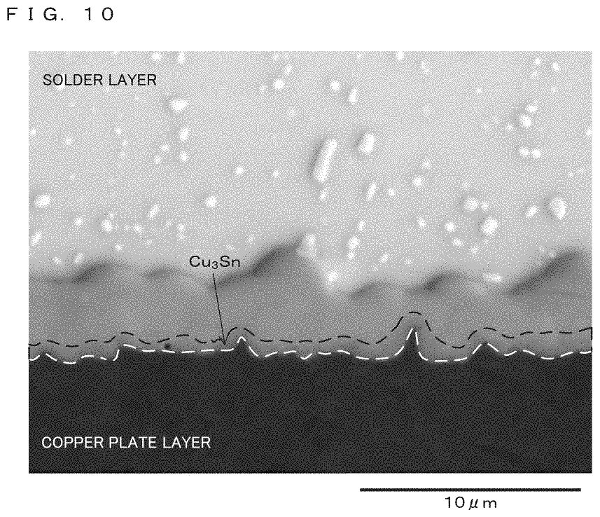

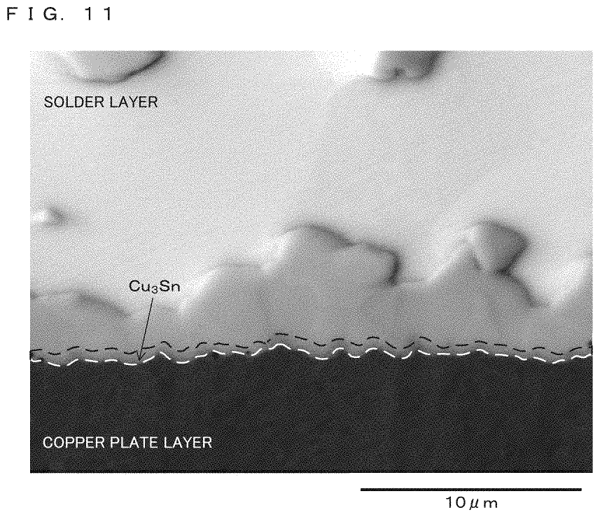

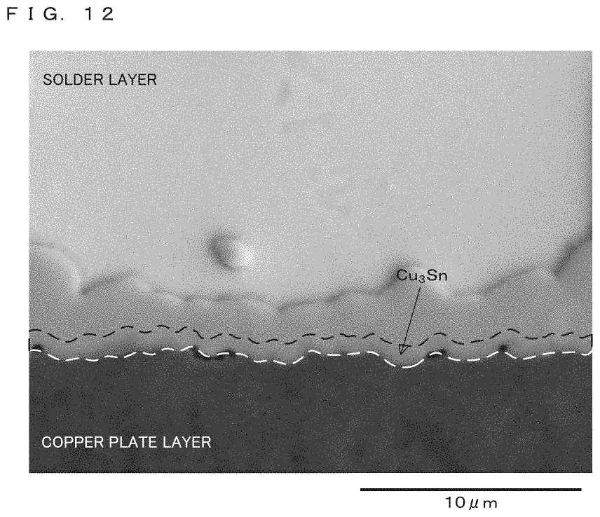

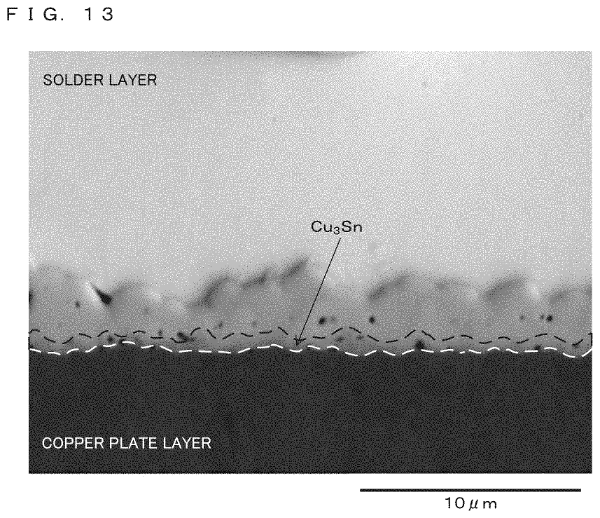

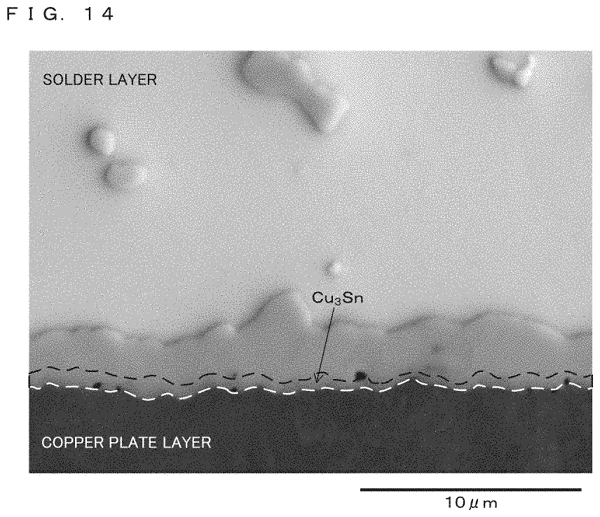

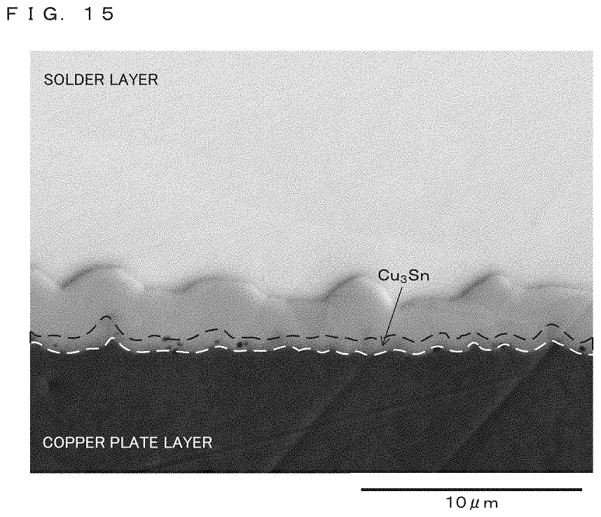

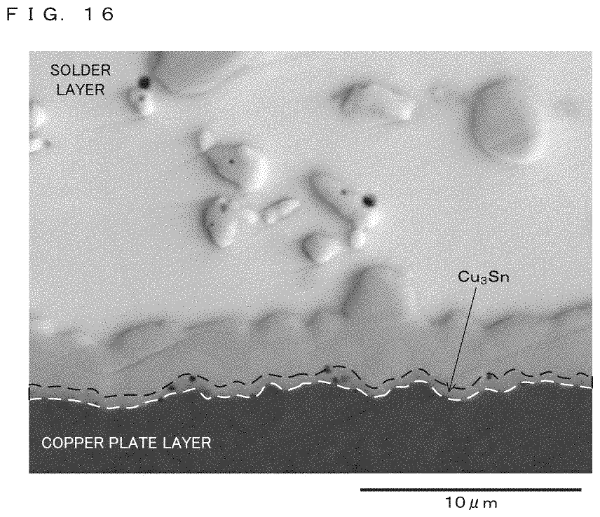

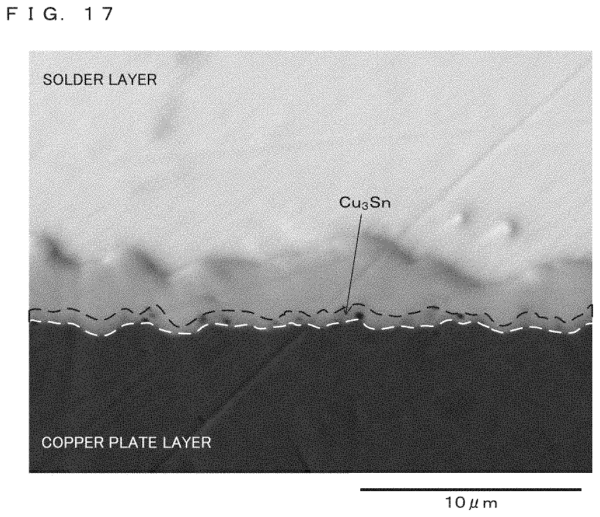

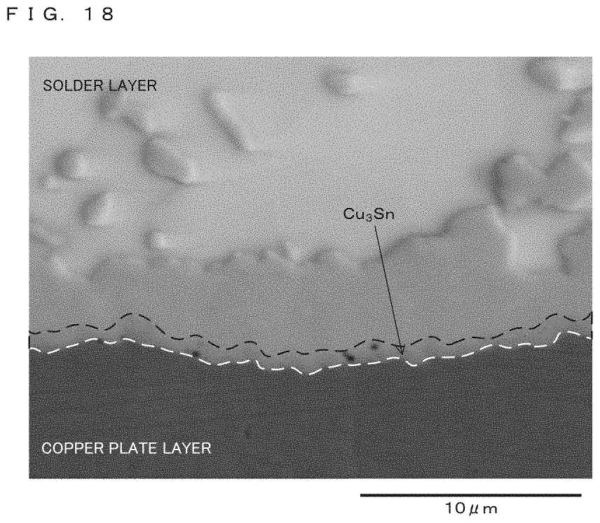

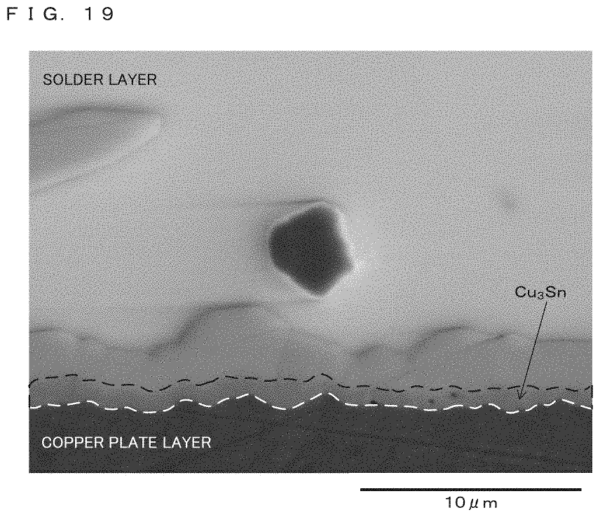

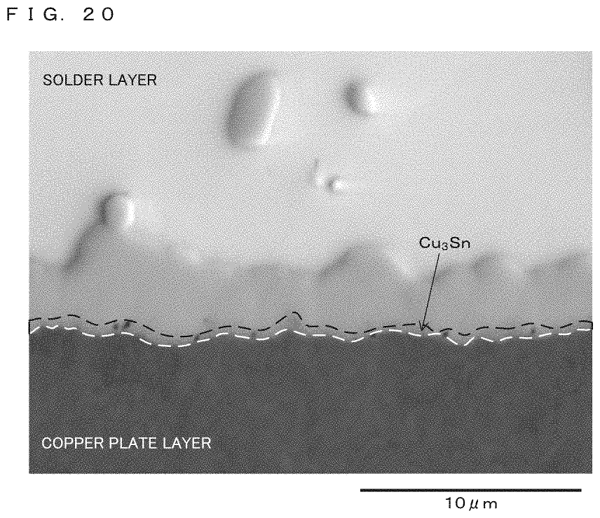

FIG. 10 to FIG. 20 are pictures illustrating the microstructure of the bonding portion 4 in the samples according to Examples 21 to 36. FIG. 10 illustrates the microstructure of the bonding portion 4 of the soldered joint 10 of Example 24 (“+4Ag”), FIG. 11 illustrates the microstructure of the bonding portion 4 of the soldered joint 10 of Example 25 (“+6In”), FIG. 12 illustrates the microstructure of the bonding portion 4 of the soldered joint 10 of Example 27 (“+5Sb”), FIG. 13 illustrates the microstructure of the bonding portion 4 of the soldered joint 10 of Example 29 (“+0.1P”), FIG. 14 illustrates the microstructure of the bonding portion 4 of the soldered joint 10 of Example 30 (“+0.1Mn”), FIG. 15 illustrates the microstructure of the bonding portion 4 of the soldered joint 10 of Example 31 (“+0.1Au”), FIG. 16 illustrates the microstructure of the bonding portion 4 of the soldered joint 10 of Example 32 (“+0.4Zn”), FIG. 17 illustrates the microstructure of the bonding portion 4 of the soldered joint 10 of Example 33 (“+0.1Si”), FIG. 18 illustrates the microstructure of the bonding portion 4 of the soldered joint 10 of Example 34 (“+0.1Co”), FIG. 19 illustrates the microstructure of the bonding portion 4 of the soldered joint 10 of Example 35 (“+0.1Al”), and FIG. 20 illustrates the microstructure of the bonding portion 4 of the soldered joint 10 of Example 36 (“+0.1Ti”).

FIG. 10 to FIG. 20 are pictures obtained by capturing the microstructure of the bonding portion 4 of each of the samples by using an electron scanning microscope (SEM) after performing the aging treatment with respect to the samples of the soldered joint 10 according to this embodiment at 150° C. for 120 hours.

As known from FIG. 10 to FIG. 20, in any of the samples according to this embodiment, the Cu₃Sn intermetallic compound layer exists in the bonding portion 4 between the solder ball 2 and the substrate 1. The thickness of the Cu₃Sn layer in the examples of FIG. 10 to FIG. 20 was calculated by the formula described above.

The calculated thickness of the Cu₃Sn layer is shown in Table 6. In Table 6, the average thickness of the Cu₃Sn layer before and after the soldered joint according to Examples 21 to 36 and Comparative Examples i and ii is subjected to the aging treatment is shown. In addition, for comparison, the strength change rate in Table 5 is also shown. As known from Table 6, in most cases, the Cu₃Sn layer does not exist before the aging treatment, but in the case of Comparative Example i and Example 28, the Cu₃Sn layer exists even before the aging treatment.

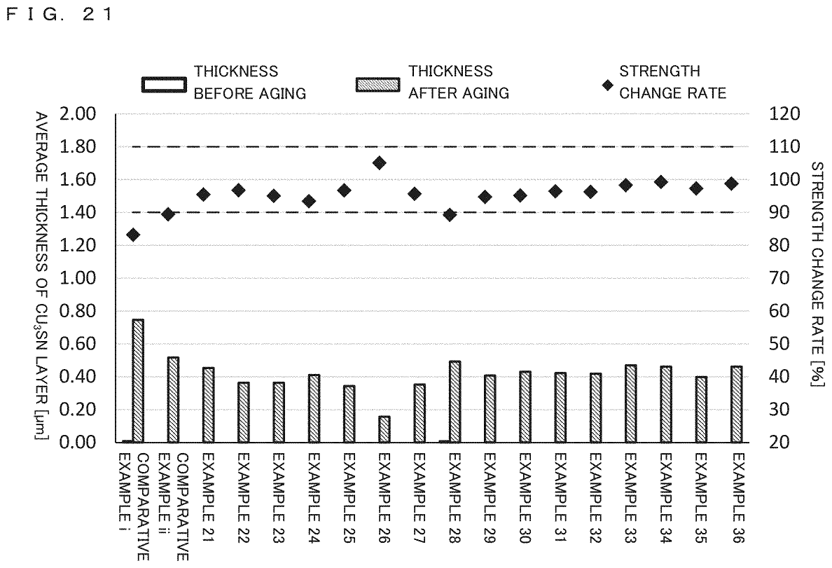

FIG. 21 is a bar graph illustrating a calculation result of the thickness of the Cu₃Sn layer shown in Table 6. In FIG. 21, a white bar (only Comparative Example i and Example 28) indicates the average thickness of the Cu₃Sn layer before the aging treatment, a black bar indicates the average thickness of the Cu₃Sn layer after the aging treatment, and a black lozenge indicates the strength change rate. Further, in FIG. 21, a range determined by two broken lines indicates the allowable range of the strength change rate.

In comparison between the case of Comparative Examples i and ii and Example 28 in which the strength change rate is out of the allowable range, and the case of Examples 21 to 27 and 29 to 36 in which the strength change rate is within the allowable range, it is seen that the thickness of the Cu₃Sn layer is divided at 0.49 μm.

Specifically, in the case of Examples 21 to 27 and 29 to 36 in which the strength change rate is within the allowable range, the thickness of the Cu₃Sn layer is less than 0.49 μm. On the other hand, in the case of Comparative Examples i and ii and Example 28 in which the strength change rate is out of the allowable range, the thickness of the Cu₃Sn layer is greater than or equal to 49 μm.

Further, in the case of Examples 24 to 28, it is possible to confirm that the strength change rate increases as the thickness of the Cu₃Sn layer decreases, and the strength change rate decreases as the thickness of the Cu₃Sn layer increases. That is, it is possible to confirm again that an increase in the thickness of the Cu₃Sn layer causes a decrease in the bonding strength after the high temperature aging treatment.

As described above, in the soldered joint 10 using the lead-free solder alloy of Sn—Cu—Ni—Bi—Ge system containing the additive, in a case where the aging treatment is performed at 150° C. for 120 hours, it is necessary to suppress the thickness of Cu₃Sn that is formed in the bonding portion 4 to be less than 0.49 μm, in order to obtain an effect of setting a change between the bonding strength before the aging treatment and the bonding strength after the aging treatment to be greater than or equal to 90%.

The additives described above have unique effects, respectively. For example, P has a unique effect such as the antioxidation of Sn and a solder component due to an oxide layer. Ti has a unique effect such as a self-oxidization effect and an increase in a bulk strength. In has a unique effect such as a decrease in a liquid phase temperature and an increase in a strength, and Ag has a unique effect such as an increase in a strength before the aging treatment due to the enhancement of precipitation and dispersion. Co has a unique effect such as the refinement of an intermetallic compound layer, Al has a unique effect such as the refinement of an intermetallic compound, the suppression of a decrease in the strength after the aging treatment, and a self-oxidization effect.

From the results described above with respect to Examples 21 to 27 and 29 to 36, it is determined that the addition of such a additive has the effects described above, and is also capable of obtaining effects unique to such a additive.

On the other hand, in Examples 1 to 7 and 10 to 14 according to Table 1, in a case where the thickness of the Cu₃Sn layer is less than or equal to 0.49 μm, the effects described above are obtained (refer to Table 3). In consideration of this, in order for such effects, it is preferable that the thickness of Cu₃Sn that is formed in the bonding portion 4 is suppressed to be less than or equal to 0.49 μm, and it is more sure that the thickness is suppressed to be less than 0.49 μm.

Furthermore, according to Table 1 and Table 4, a difference between the solid phase point and the liquid phase point in Examples 8, 9, and 28 in which the strength change rate is out of the allowable range is greater than that in other examples in which the strength change rate is within the allowable range. Specifically, in Examples 8, 9, and 28, the difference between the solid phase point and the liquid phase point is approximately greater than or equal to 30, in most of the other examples, the difference is less than 30. Accordingly, in this embodiment, in order to obtain the effects described above, it is also effective that the difference between the solid phase point and the liquid phase point is suppressed to be less than or equal to 30.

As described above, in the soldered joint 10 according to this embodiment, the Cu₃Sn layer is prevented from being generated in the bonding portion 4, and thus, even in a case where the soldered joint 10 is left in a high temperature environment, it is possible to prevent a decrease in the bonding strength due to the generation of the Cu₃Sn layer. In addition, it is needless to say that such an effect is affected by the addition of Bi. This is obvious from the fact that the soldered joints 10 according to this embodiment (the bonding portion 4) contain Bi in common, the soldered joints according to Comparative Examples i and ii not having such an effect do not contain Bi.

The soldered joints 10 using the lead-free solder alloy of Sn—Cu—Ni—Bi—Ge system and the lead-free solder alloy to which the additive is added, according to this embodiment (hereinafter, collectively referred to as the soldered joint according to this embodiment) have an effect of maintaining the bonding strength after the aging treatment with respect to the bonding strength before the aging treatment even in the case of being subjected to the aging treatment at a high temperature for a long period of time.

In consideration of such an effect, in the soldered joint 10 according to this embodiment, it is also possible to expect an effect of suppressing so-called creep deformation by adding Bi. Therefore, creep properties of the soldered joint 10 according to this embodiment were observed.

Test pieces for a creep test was prepared by using the lead-free solder alloys of the component compositions according to Examples 1 to 14 and Examples 21 to 36 described above, and lead-free solder alloys having the same component compositions as that of Example 2 except that Bi was 1.1 weight % and 1.2 weight %, respectively. Further, a test piece for a creep test was prepared by using a lead-free solder alloy in which 1 weight % of Ga was added to the component composition according to Example 3. By using such test pieces of the component compositions, the creep properties were evaluated. Hereinafter, for convenience of description, the lead-free solder alloy having the same component composition as that of Example 2 except that Bi is 1.1 weight % will be referred to as Example 2-1, and the lead-free solder alloy having the same component composition as that of Example 2 except that Bi is 1.2 weight % will be referred to as Example 2-2. In addition, the lead-free solder alloy in which 1 weight % of Ga is added to the component composition according to Example 3 will be referred to as Example 37. Furthermore, hereinafter, Examples 1 to 14 and Example 2-1 and Example 2-2 will be referred to as Examples 1 to 14.

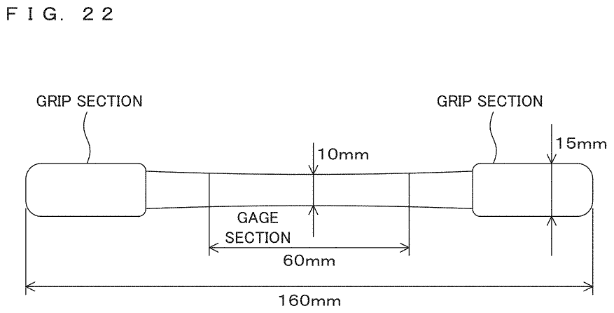

FIG. 22 is an exemplary diagram illustrating an example of the test piece that is used in the evaluation of the creep properties. A so-called dog bone type test piece was used as the test piece. As illustrated in FIG. 22, the test piece has a total length of 160 mm, a gage length of 60 mm, a gage width of 10 mm, and a grip section width of 15 mm. The test was performed by using tension tester (AG-IS 10KN, manufactured by Shimadzu Corporation).

Specifically, the dog bone type test piece was set in a chamber of the tension tester by fixing the grip section, and then, the test piece was heated, a tension test was started at a time point when the temperature in the center of the rating portion of the test piece reached 125° C. A tension stress of 120 kgf (1177 N) was continuously applied to the test piece, and a time until fracture and a strain amount were measured. At this time, a value was obtained by dividing a change rate of the gage length after the fracture (a length when end surfaces of a fracture portion abutted against each other) with respect to the gage length before starting the test by the time until the fracture and the value was set to a “strain rate”.

Table 7 is an evaluation result of the creep properties of the test pieces using the lead-free solder alloys of the component compositions according to Examples 1 to 14 and Examples 21 to 36. In Table 7, the strain rate and the time until the fracture (hereinafter, referred to as a fracture time) are shown. In addition, in Table 7, for comparison, an evaluation result of the creep properties of the test pieces according to Comparative Examples i and ii is also shown.

TABLE 7

| | Component Composition | Strain Rate | Fracture Time |
|---|---|---|---|
| No. | (unit: wt %) | (%/min) | (min) |
| Comparative | Sn 3.0Ag 0.5Cu | 0.16 | 192 |
| Example i | | | |
| Comparative | Sn 0.7Cu 0.05Ni 0.006Ge | (※) | (※) |
| Example ii | | | |
| Example 1 | Sn 0.7Cu 0.00Ni 0.006Ge 0.1Bi | 1.85 | 13 |
| Example 2 | Sn 0.7Cu 0.05Ni 0.006Ge 1Bi | 0.10 | 222 |
| Example 2-1 | Sn 0.7Cu 0.05Ni 0.006Ge 1.1Bi | 0.08 | 242 |
| Example 2-2 | Sn 0.7Cu 0.05Ni 0.006Ge 1.2Bi | 0.08 | 258 |
| Example 3 | Sn 0.7Cu 0.05Ni 0.006Ge 1.5Bi | 0.07 | 273 |
| Example 4 | Sn 0.7Cu 0.05Ni 0.006Ge 2Bi | 0.04 | 302 |
| Example 5 | Sn 0.7Cu 0.05Ni 0.006Ge 3Bi | 0.01 | 368 |
| Example 6 | Sn 0.7Cu 0.05Ni 0.006Ge 4Bi | 0.02 | 332 |
| Example 7 | Sn 0.7Cu 0.05Ni 0.006Ge 6Bi | 0.05 | 219 |
| Example 8 | Sn 0.7Cu 0.05Ni 0.006Ge 8Bi | 0.07 | 144 |
| Example 9 | Sn 0.7Cu 0.05Ni 0.006Ge 21Bi | 5.19 | 4 |
| Example 10 | Sn 0 7Cu 0.05Ni 0.006Ge 58Bi | (※) | (※) |
| Example 11 | Sn 0.1Cu 0.05Ni 0.006Ge 1.5Bi | 0.05 | 296 |
| Example 12 | Sn 2.0Cu 0.05Ni 0.006Ge 1.5Bi | 0.09 | 288 |
| Example 13 | Sn 0.7Cu 0.5Ni 0.006Ge 1.5Bi | 0.03 | 550 |
| Example 14 | Sn 0.7Cu 0.05Ni 0.1Ge 1.5Bi | 0.01 | 810 |
| Example 21 | Sn 0.7Cu 0.05Ni 0.006Ge 1.5Bi 1Ag | 0.02 | 640 |
| Example 22 | Sn 0.7Cu 0.05Ni 0.006Ge 1.5Bi 2Ag | 0.03 | 643 |
| Example 23 | Sn 0.7Cu 0.05Ni 0.006Ge 1.5Bi 3Ag | 0.05 | 437 |
| Example 24 | Sn 0.7Cu 0.05Ni 0.006Ge 1.5Bi 4Ag | 0.05 | 383 |
| Example 25 | Sn 0.7Cu 0.05Ni 0.006Ge 1.5Bi 6In | 0.07 | 236 |
| Example 26 | Sn 0.7Cu 0.05Ni 0.006Ge 1.5Bi 51In | (※) | (※) |
| Example 27 | Sn 0.7Cu 0.05Ni 0.006Ge 1.5Bi 5Sb | 0.01 | 535 |
| Example 28 | Sn 0 7Cu 0.05Ni 0.006Ge l.5Bi 10Sb | 0.01 | 691 |
| Example 29 | Sn 0.7Cu 0.05Ni 0.006Ge 1.5Bi 0.1P | 0.02 | 516 |
| Example 30 | Sn 0.7Cu 0.05Ni 0 006Ge 1.5Bi 0.1Mn | 0.05 | 291 |
| Example 31 | Sn 0.7Cu 0.05Ni 0.006Ge 1.5Bi 0.1Au | 0.05 | 397 |
| Example 32 | Sn 0 7Cu 0.05Ni 0.006Ge 1.5Bi 0.1Zn | 0.01 | 151 |
| Example 33 | Sn 0.7Cu 0.05Ni 0.006Ge 1.5Bi 0.1Si | 0.09 | 163 |
| Example 34 | Sn 0.7Cu 0.05Ni 0.006Ge 1.5Bi 0.1Co | 0.03 | 423 |
| Example 35 | Sn 0.7Cu 0.05Ni 0.006Ge 1.5Bi 0.1Al | 0.18 | 100 |
| Example 36 | Sn 0 7Cu 0.05Ni 0.006Ge 1.5Bi 0.1Ti | 0.01 | 243 |
| Example 37 | Sn 0.7Cu 0.0SNi 0.006Ge 1.5Bi 1Ga | 0.12 | 22 |

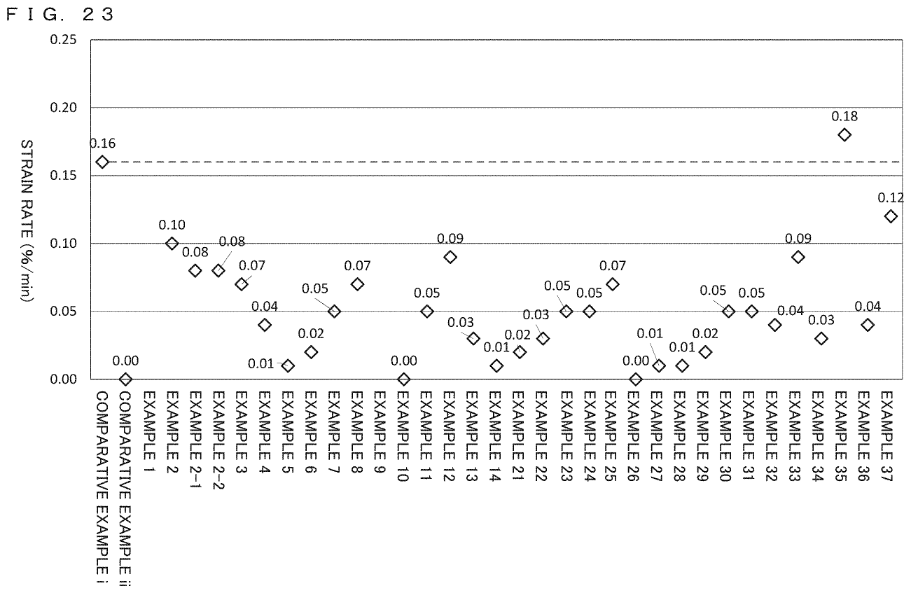

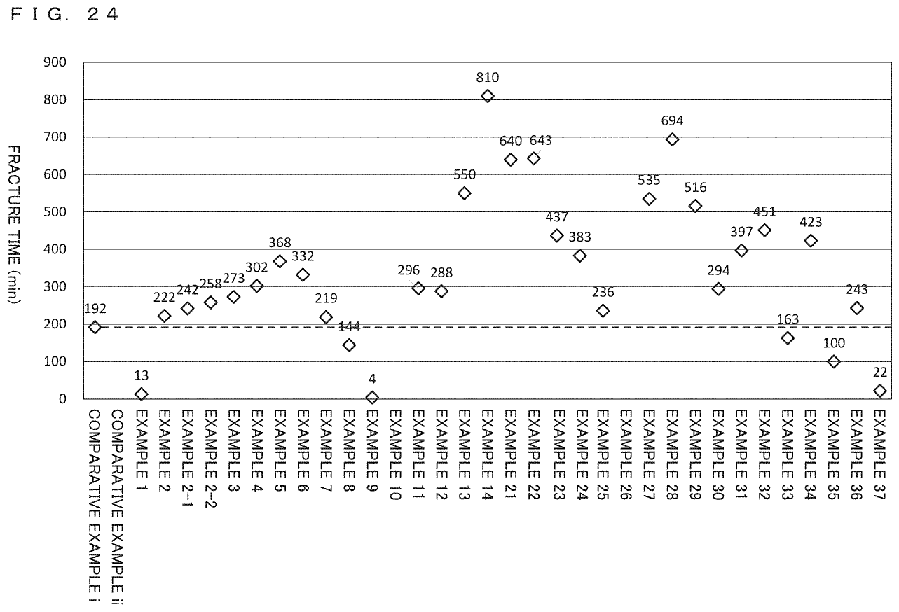

FIG. 23 and FIG. 24 are graphs illustrating the evaluation result of the creep properties shown in Table 7. FIG. 23 illustrates the strain rate, in the evaluation result of the creep properties shown in Table 7, and FIG. 24 illustrates the fracture time, in the evaluation result of the creep properties shown in Table 7.

In Table 7, the strain rate lower than the strain rate according to Comparative Examples i and ii, and the fracture time longer than the fracture time according to Comparative Examples i and ii were colored (with gray). In Table 7, “x” indicates that the evaluation of the creep properties was unavailable.

In addition, in FIG. 23, a horizontal axis and a vertical axis indicate the component composition and the strain rate, respectively, a white lozenge indicates the rate of the strain corresponding to each of the component compositions, and a broken line indicates a value according to Comparative Examples i and ii. Further, in FIG. 23, the case of Example 9 in which the strain rate is extremely high is not illustrated. Then, in FIG. 24, a horizontal axis and a vertical axis indicate the component composition and the fracture time, respectively, a white lozenge indicates the fracture time corresponding to each of the component compositions, and a broken line indicates a value according to Comparative Examples i and ii.

As known from Table 7, FIG. 23 and FIG. 24, the creep properties in Example 2 to Example 8 (including Example 2-1 and Example 2-2), Example 11 to Example 14, Example 21 to Example 25, Example 27 to Example 34, and Example 36 to Example 37 were excellent compared to the test piece according to Comparative Example i (Comparative Example ii was not measurable).

That is, in the strain rate, the values according to Example 2 (“+1Bi”) to Example 8 (“+8Bi”) (including Example 2-1 and Example 2-2), Example 11 (“+0.1Cu”) to Example 14 (“+0.1Ge”), Example 21 (“+1Ag”) to Example 25 (“+6In”), Example 27 (“+5Sb”) to Example 34 (“+0.1Co”), and Example 36 (“+0.1Ti”) to Example 37 are less than the value according to Comparative Example i.

On the other hand, in the fracture time, the values according to Example 2 (“+1Bi”) to Example 7 (“+6Bi”), Example 11 (“+0.1Cu”) to Example 14 (“+0.1Ge”), Example 21 (“+1Ag”) to Example 25 (“+6In”), Example 27 (“+5Sb”) to Example 32 (“+0.4Zn”), Example 34 (“+0.1Co”), and Example 36 (“+0.1Ti”) are greater than the value according to Comparative Example i.

In Table 7, in a case where the composition of Bi was changed from 0.1 weight % to 58 weight % (Example 1 to Example 10) (including Example 2-1 and Example 2-2), creep properties equivalent to or better than those of Comparative Example i were observed within a range in which Bi was 1 weight % to 6 weight % (Example 2 to Example 7). However, it was seen that the fracture time tended to be shorter than that of Comparative Example i, from a case where Bi was 8 weight % (Example 8). It is considered that this is because solid-solution enhancement of Bi works excessively, and the lead-free solder alloy is changed to have hard and brittle properties. In addition, excessive Bi is precipitated, and an influence on a fracture propagation by stress concentration on the precipitated Bi is also predicted.

In the test pieces containing 1 weight % to 8 weight % of Bi (Example 2 to Example 8) in which the strain rate is better than that of Comparative Example i, the strain rate decreases within a range in which Bi is 1 weight % to 3 weight %, in a case where Bi is more than 3 weight %, the strain rate is started to gradually increase, and in a case where Bi is more than 4 weight %, the strain rate rapidly increases.

In addition, in the test pieces containing 1 weight % to 6 weight % of Bi (Example 2 to Example 7) in which the fracture time is equivalent to or better than that of Comparative Example i, the fracture time increases within a range in which Bi is 1 weight % to 3 weight %, and in a case where Bi is more than 3 weight %, the fracture time is started to decrease.

From the above description, the creep properties in a case where the composition of Bi is changed (Example 1 to Example 10) are effective in the lead-free solder alloys of Example 2 to Example 7 (including Example 2-1 and Example 2-2) in which the addition amount of Bi is 1 weight % to 6 weight %. In addition, the creep properties are most effective in Example 5 in which the addition amount of Bi is 3 weight %.

In Table 7, in a case where the composition of Cu was changed from 0.1 weight % to 2.0 weight % (Example 3, Example 11, and Example 12), it was observed that both of the strain rate and the fracture time were better than those of Comparative Example i.

In particular, in a case where Cu is more than 0.1 weight %, the strain rate increases, and the fracture time decreases. Accordingly, it is known that the creep properties in a case where the composition of Cu is changed (Example 3, and Example 11 to Example 12) are most effective in the lead-free solder alloy of Example 11 in which the addition amount of Cu is 0.1 weight %.

In Table 7, in a case where the composition of Ni was changed from 0.05 weight % to 0.5 weight % (Example 3 and Example 13), it was observed that both of the strain rate and the fracture time were better than those of Comparative Example i. In particular, the strain rate decreases, and the fracture time increases, as the addition amount of Ni increases.

In Table 7, in a case where the composition of Ge was changed from 0.006 weight % to 0.1 weight % (Example 3 and Example 14), it was observed that both of the strain rate and the fracture time were better than those of Comparative Example i. In particular, the strain rate decreases, and the fracture time increases, as the addition amount of Ge increases.

In addition, in the case (Example 21 to Example 25, Example 27 to Example 32, Example 34, and Example 36) where one additive out of Ag, In, Sb, P, Mn, Au, Zn, Co, and Ti is added to the component composition according to Example 3, the creep properties are better than those of Comparative Example i. That is, even in a case where such an additive is added, the effect associated with the creep properties obtained by adding Bi is not inhibited.

In Table 7, in a case where the composition of Ag was changed from 1 weight % to 4 weight % (Example 21 to Example 24), it was observed that both of the strain rate and the fracture time were better than those of Comparative Example i.

In particular, in a case where Ag is more than 1 weight %, the strain rate gradually increases, and in a case where Ag is more than 2 weight %, the strain rate rapidly increases. In addition, the fracture time increases within a range in which Ag is 1 weight % to 2 weight %, and in a case where Ag is more than 2 weight %, the fracture time rapidly decreases.

From the above description, it is known that the creep properties in a case where the composition of Ag is changed (Example 21 to Example 24) are most effective in the lead-free solder alloy of Example 22 in which the addition amount of Ag is 2 weight %.

As described above, the soldered joint 10 according to this embodiment has excellent creep properties. That is, the soldered joint 10 according to this embodiment has an effect of suppressing the creep deformation, and has small creep deformation. Accordingly, for example, in electronic products in which the soldered joint 10 according to this embodiment is used, even in a case where an electronic substrate temperature increases while the electronic products operate, a deformation amount of a solder (a connecting portion) is small with respect to a stress load on a solder connecting portion, and age deterioration is also suppressed.

### DESCRIPTION OF REFERENCE NUMERALS

1 Substrate

2 Solder ball

4 Bonding portion

10 Soldered joint

It is noted that, as used herein and in the appended claims, the singular forms “a”, “an”, and “the” include plural referents unless the context clearly dictates otherwise.

As this invention may be embodied in several forms without departing from the spirit of essential characteristics thereof, the present embodiments are therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1-7. (canceled)

8. A soldered joint using a lead-free solder alloy, the lead-free solder alloy containing Sn, Cu, Ni, Bi and Ge, the soldered joint comprising:
a bonding portion with an object to be soldered in which Cu₃Sn is prevented from being generated, wherein
in the lead-free solder alloy, an addition amount of Cu is 0.1 weight % to 2.0 weight %, an addition amount of Ni is 0.05 weight % to 0.5 weight %, an addition amount of Bi is 0.1 weight % to less than 8 weight %, an addition amount of Ge is 0.006 weight % to 0.1 weight %, and a balance is Sn and inevitable impurities.

9. The soldered joint according to claim 8, wherein
in the lead-free solder alloy, one or two or more selected from the group consisting of Ag, In, Sb, P, Mn, Au, Zn, Si, Co, Al, and Ti are added, an addition amount of Ag is more than 0 weight % to 4.0 weight %, an addition amount of In is more than 0 weight % to 51.0 weight %, an addition amount of Sb is more than 0 weight % and less than 10.0 weight %, an addition amount of Zn is more than 0 weight % to 0.4 weight %, and an addition amount of P, Mn, Au, Si, Co, Al, or Ti is more than 0 weight % to 0.1 weight %.

10. The soldered joint according to claim 8, wherein
in a case where an aging treatment is performed at 150° C. for 120 hours, a change between a shear load stress before the aging treatment and a shear load stress after the aging treatment is greater than or equal to 90%.

11. The soldered joint according to claim 8, wherein
in a case where the aging treatment is performed at 150° C. for 120 hours, a thickness of Cu3Sn that is formed in the bonding portion is less than or equal to 0.50 μm.

12. The soldered joint according to claim 8, wherein
the addition amount of Bi is 1.0 weight % to 3.0 weight %.

13. The soldered joint according to claim 9, wherein
the addition amount of Ag is 1.0 weight % to 4.0 weight %.

14. The soldered joint according to claim 9, wherein
the addition amount of Sb is more than 0 weight % to 5.0 weight %.
